(19) United States
(12) Patent Application Publication
(10) Pub. No.: US 2010/0319774 A1
(43) Pub. Date: Dec. 23, 2010

(54) SOLAR CONCENTRATOR WITH SIMPLIFIED TRACKING

(75) Inventor: Peter v Schwartz, San Luis Obispo, CA (US)

Correspondence Address: Peter V. Schwartz, 1441 Iris Street, San Luis Obispo, CA, 93401, US

(73) Assignee: Peter V Schwartz, San Luis Obispo, CA (US)

(21) Appl. No.: 12/665,711

(22) PCT Filed: Jun. 18, 2008
(86) PCT No.: PCT/US08/67254

§ 371 Date: Dec. 18, 2009

Related U.S. Application Data
(60) Provisional application No. 60/944,763, filed on Jun. 18, 2007.
(60) Provisional application No. 60/957,615, filed on Aug. 23, 2007.
(60) Provisional application No. 60/970,439, filed on Sep. 6, 2007.

(51) Int. Cl. H01L 31/04; F24J 2/40

(52) U.S. Cl. 136/259; 126/572

(57) ABSTRACT

An apparatus for diverting light energy comprising a target, wherein the target is configured for collecting the light energy from a light source and a light bending element disposed in a light path of at least one ray of the light energy between the light source and the target, wherein the light bending element is configured for collection of the light energy as an angle of incidence of at least one ray of the light energy changes over time relative to the light bending element, the light bending element is configured to direct the light energy to the target, wherein the light bending element and the target move relative to each other, movement of the light bending element and the target relative to each other being a function of at least the angle of incidence of at least one ray of the light energy.

This application claims the benefit of U.S. Provisional Application No. 60/944,763, filed Jun. 18, 2007 (MOBILE FOCAL POINT SOLAR FOCUSING) which is incorporated in its entirety herein by reference.

This application claims the benefit of U.S. Provisional Application No. 60/957,615, filed Aug. 23, 2007 (MOBILE LENS, FOCUS, AND MIRROR SOLAR FOCUSING) which is incorporated in its entirety herein by reference.

This application claims the benefit of U.S. Provisional Application No. 60/970,439, filed Sep. 6, 2007 (STATIONARY HEAT COLLECTING ELEMENT SOLAR FOCUSING, AND POOL HEATING) which is incorporated in its entirety herein by reference.

This application claims the benefit of PCT Patent Application PCT/US08/67254 filed Jun. 18, 2008 (SOLAR CONCENTRATOR WITH SIMPLIFIED TRACKING) which is incorporated in its entirety herein by reference.

### BACKGROUND OF THE INVENTION

1. Field of the Invention

The present invention relates generally to directing light energy from a light source, and more specifically to directing solar energy form the sun to an absorbing element to harvest the solar energy.

2. Discussion of the Related Art

Directing light energy from a light source, such as solar energy from the sun, provides a useful tool in utilizing alternate sources of power. One strategy is to utilize a device which absorbs and harvests the light energy. Such devices can be a photovoltaic cell, which converts solar energy into electricity.

A concentrator is utilized to focus the light energy from the light source to the absorbing device. With the sun as the light source, the concentrator captures solar energy shining over a large area and focuses the solar energy onto a smaller area of the absorbing element. However, as the sun moves around the sky during the day and in the course of a year, a stationary concentrator may be unable to focus the solar energy to the small area of the absorbing element.

### SUMMARY OF THE INVENTION

Several embodiments of the invention advantageously address the needs above as well as other needs by providing an apparatus for diverting light energy comprising a target, wherein the target is configured for collecting the light energy from a light source and a light bending element disposed in a light path of at least one ray of the light energy between the light source and the target, wherein the light bending element is configured for collection of the light energy as an angle of incidence of at least one ray of the light energy changes over time relative to the light bending element, the light bending element is configured to direct the light energy to the target, wherein the light bending element and the target move relative to each other, movement of the light bending element and the target relative to each other being a function of at least the angle of incidence of at least one ray of the light energy.

In another embodiment, the invention can be characterized as a method for directing light energy comprising receiving at least one ray of the light energy at a light bending element at an angle of incidence upon the light bending element, wherein the light bending element is disposed in a light path of at least one ray of the light energy between a light source and a target, directing at least one ray of the light energy from the light bending element to the target, moving the light bending element and the target relative to each other, wherein movement of the light bending element and the target relative to each other being a function of at least an angle of incidence of at least one ray of the light energy, and collecting the at least one ray of the light energy at the target.

In a further embodiment, the invention provides a method for heating a flowable material, comprising applying a heat absorbing layer to at least a portion of a container, wherein the container houses the flowable material, absorbing light energy at the heat absorbing layer and releasing the light energy as heat form the heat absorbing layer to the flowable material in the container.

### BRIEF DESCRIPTION OF THE DRAWINGS

The above and other aspects, features and advantages of several embodiments of the present invention will be more apparent from the following more particular description thereof, presented in conjunction with the following drawings.

FIGS. 1A, 1B, and 1C are cross sectional views of an apparatus during equinox, summer, and winter lighting conditions in accordance with one embodiment of the present invention.

FIGS. 2A, 2B, and 2C are cross sectional views of an apparatus during equinox, summer, and winter lighting conditions in accordance with another embodiment of the present invention.

FIGS. 3A, 3B, and 3C are cross sectional views of an apparatus during equinox, summer, and winter lighting conditions in accordance with another embodiment of the present invention.

FIGS. 4A, 4B, and 4C are cross sectional views of an apparatus during equinox, summer, and winter lighting conditions in accordance with another embodiment of the present invention.

FIGS. 5A, 5B, and 5C are cross sectional views of an apparatus during equinox, summer, and winter lighting conditions in accordance with another embodiment of the present invention.

FIGS. 6A, 6B, and 6C are cross sectional views of an apparatus during equinox, summer, and winter lighting conditions in accordance with another embodiment of the present invention.

FIGS. 7A, 7B, and 7C are cross sectional views of an apparatus during equinox, summer, and winter lighting conditions in accordance with another embodiment of the present invention.

FIG. 8A, is a cross sectional view of an apparatus in accordance with another embodiment of the present invention.

FIG. 8B is a cross sectional view illustrating the movement of the apparatus of FIG. 8A.

FIG. 8C is a close up view of the apparatus of FIG. 8A.

FIG. 9A is a cross sectional view of an apparatus in accordance with another embodiment of the present invention.

FIG. 9B is a cross sectional view illustrating the movement of the apparatus of FIG. 9A.

FIG. 9C is a close up view of the apparatus of FIG. 9A.

FIGS. 10A, 10B, and 10C are cross sectional views of an apparatus during equinox, summer, and winter lighting conditions in accordance with one embodiment of the present invention.

FIGS. 11A, 11B, and 11C are cross sectional views of an apparatus during equinox, summer, and winter lighting conditions in accordance with one embodiment of the present invention.

FIGS. 12A, 12B, and 12C are cross sectional views of an apparatus utilizing a follower in accordance with embodiment of the present invention.

FIGS. 13A, 13B, and 13C are cross sectional views illustrating a support device of an apparatus in accordance with one embodiment of the present invention.

FIGS. 14A, 14B, and 14C are cross sectional views illustrating a support component of an apparatus in accordance with one embodiment of the present invention.

FIGS. 15A, 15B, and 15C are cross sectional views illustrating a support component of an apparatus in accordance with one embodiment of the present invention.

FIGS. 16A and 16B are cross sectional views illustrating positioning of a target in accordance with one embodiment of the present invention.

FIG. 17 is a diagram illustrating simulation results of an apparatus in accordance with one embodiment of the present invention.

FIG. 18A is a graphical illustration of a shape of an apparatus in accordance with one embodiment of the present invention.

FIG. 18B is a chart depicting the graph points of the graphical illustration of FIG. 18A.

FIG. 19 is another graphical illustration of a shape of an apparatus in accordance with one embodiment of the present invention.

FIG. 20 is a graphical illustration of power versus rotation angle for an apparatus in accordance with an embodiment of the present invention.

FIG. 21 is a photo depicting an apparatus in accordance with an embodiment of the present invention.

FIGS. 22A and 22B are three dimensional views of a container utilizing a light absorbing layer in the northern or southern hemisphere in accordance with another embodiment of the present invention.

FIGS. 23A and 23B are three dimensional views of the container of FIGS. 22A and 22B utilizing the light absorbing layer in the northern or southern hemisphere in accordance with another embodiment of the present invention.

FIG. 24 is a three dimensional view of the container of FIGS. 22A and 22B utilizing the light absorbing layer in accordance with another embodiment of the present invention.

FIGS. 25A and 25B are three dimensional views of the container of FIGS. 22A and 22B utilizing the light absorbing layer in the northern or southern hemisphere in accordance with another embodiment of the present invention.

FIGS. 26A and 26B are three dimensional views of the container of FIGS. 22A and 22B utilizing the light absorbing layer in the northern or southern hemisphere in accordance with another embodiment of the present invention.

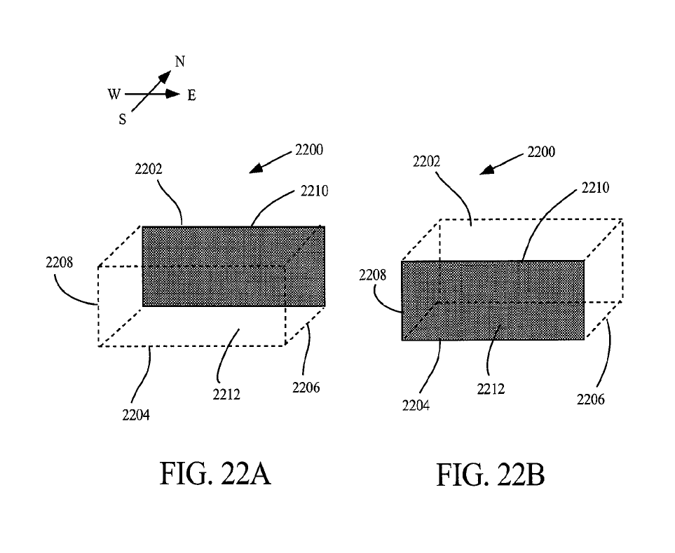

FIGS, 27A and 27B are three dimensional views of the container of FIGS. 22A and 22B utilizing the light absorbing layer in the northern or southern hemisphere in accordance with another embodiment of the present invention.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention.

### DETAILED DESCRIPTION

The following description is not to be taken in a limiting sense, but is made merely for the purpose of describing the general principles of exemplary embodiments. The scope of the invention should be determined with reference to the claims.

Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Focusing solar radiation to an absorbing element plays a pivotal role in harvesting solar energy. The absorbing element may comprise a photovoltaic cell which directly converts photons into electricity. In another embodiment, the absorbing element comprises a contained working fluid which in turn is used to turn a turbine or power a compressor. In general, the absorbing element may be a device which utilizes an intense source of heat or light. Focusing devices (such as a parabolic mirror or lens) may be used to concentrate solar energy shining over a large area and focuses the solar energy onto a smaller area. However, as the sun moves across the sky during the day and in the course of the year, the focusing device may inadvertently direct the sunlight away from the absorbing element. Therefore, focusing geometries to track the sun and focus the solar energy to an absorbing element utilizing a light bending element may greatly enhance the harvesting of solar energy.

The embodiments described herein specifically refer to light waves/rays and solar energy. Although, it should be understood that the embodiments of the present invention may be utilized with many different types of waves which propagate through a medium at various wavelengths and frequencies with corresponding wave energy. A few examples include sound waves, compression waves, ocean waves, water waves and radar waves,

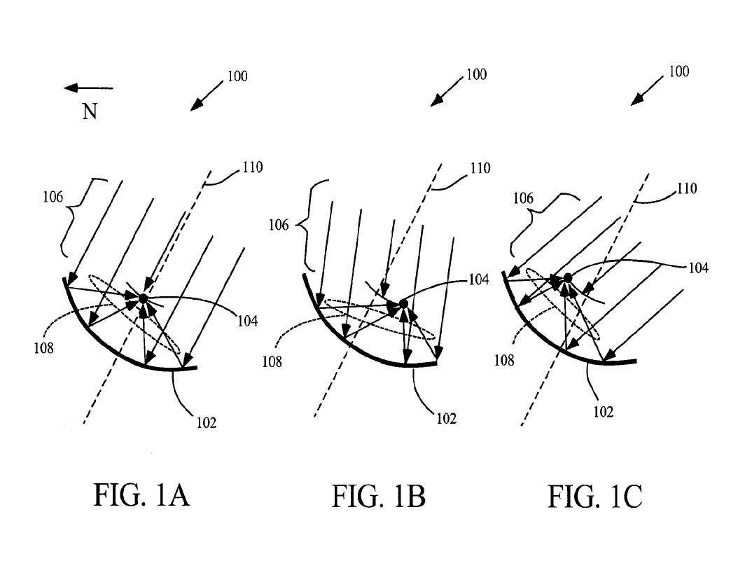

Referring first to FIGS. 1A, 1B, and 1C, cross sectional views of an apparatus 100 during equinox, summer, and winter lighting conditions in accordance with one embodiment of the present invention is illustrated comprising light bending element 102, target 104, incoming light rays 106, directed light rays 108, and primary axis 110 of the light bending element 102.

FIG. 1A exemplifies one embodiment of the apparatus 100 during equinox lighting conditions. The light bending element is located at about 30 degree N latitude and the primary axis 110 of the light bending element 102 is roughly tilted at 30 degrees from the vertical to direct light incoming at any angle. At equinox, the incoming light rays 106 from a light source strike the light bending element 102 at an incident angle of about 30 degrees (or parallel with the primary axis 110). It should be appreciated that the primary light bending element may be located at any latitude and therefore the primary light bending element may be tilted at any axis angle to correspond to equinox lighting conditions. In addition, the primary light bending element may be tilted at any axis angle to correspond with solstice conditions or to prioritize winter or summer conditions, or morning or evening light. Further, the tilting of the primary light bending element may be further modified to account for the slope of the surface which the primary light bending element rests or for various weather conditions.

The light bending element 102 is disposed in the light path of the light energy between a light source and the target 104. In one embodiment, the light source may be the sun, light energy may be solar energy, and the light path represents the path of the solar rays to the target. The incoming light rays 106 travel to the light bending element 102 from a light source. Then the directed light rays 108 leave the light bending element 102 and travel to the target 104. The target 104 is positioned at the area which the light bending element 102 focuses the directed light rays 108.

The light bending element 102 receives the incoming light rays 106 from a light source. As the incoming light rays 106 interface with the light bending element 102, the light bending element 102 directs the incoming light rays 106. In one embodiment, the light bending element 102 is shaped to direct the incoming light rays 106 to the target 104. The directed incoming light rays 106 is exemplified as directed light rays 108, the directed light rays 108 then travel to the target 104.

In one embodiment, the light bending element 102 is a reflective minor shaped to direct the incoming light rays 106 to the target 104. The target 104 may be a light energy absorbing element such as a photovoltaic array or an enclosed working fluid. The light bending element 102 then reflects the incoming light rays 106 towards the target 104. The reflected incoming light rays are exemplified as the directed light rays 108.

FIG. 1B exemplifies one embodiment of the apparatus 100 during summer lighting conditions. As illustrated, the incident angle of the incoming light rays 106 strike the light bending element 102 at about 6.5 degrees from the vertical (rather than the 30 degrees illustrated in FIG. 1A) while the light bending element remains tilted on its primary axis 110. The incoming light rays 106 strike the light bending element 102 and is directed as directed light rays 108 towards the target 106. Since the incident angle of the incoming light rays 106 is closer to the vertical, the area of focus of the directed light rays 108 shifts and the directed light rays 108 travel towards the right of the light bending element 102. The target 102 then moves to the area which the light bending element 102 focuses the directed light rays 108. Since the target 104 is mobile, this allows the apparatus 100 to collect a greater amount of light energy (solar energy) than if the target 104 and the light bending element 102 remained stationary. In addition to improving the efficiency of collecting light energy, the various embodiments of the present invention may also improve the concentration power of the light energy. In particular, the light energy may be focused to a much smaller target than previous configurations for collecting light energy.

FIG. 1C illustrates one embodiment of the apparatus 100 during winter lighting conditions. As illustrated, the incident angle of the incoming light rays 106, as the incoming light rays 106 strike the light bending element 102, shifts farther away from the vertical than illustrated with respect to FIGS. 1A and 1C during equinox and summer lighting conditions. As a result, the area of focus of the directed light rays 108 shifts towards the left of the light bending element 102. The target 102 then moves to the area which the light bending element 102 focuses the directed light rays 108. In another embodiment of the present invention, the target 104 remains stationary while the light bending element 102 moves such that the target is in the area of focus of the directed light rays 108.

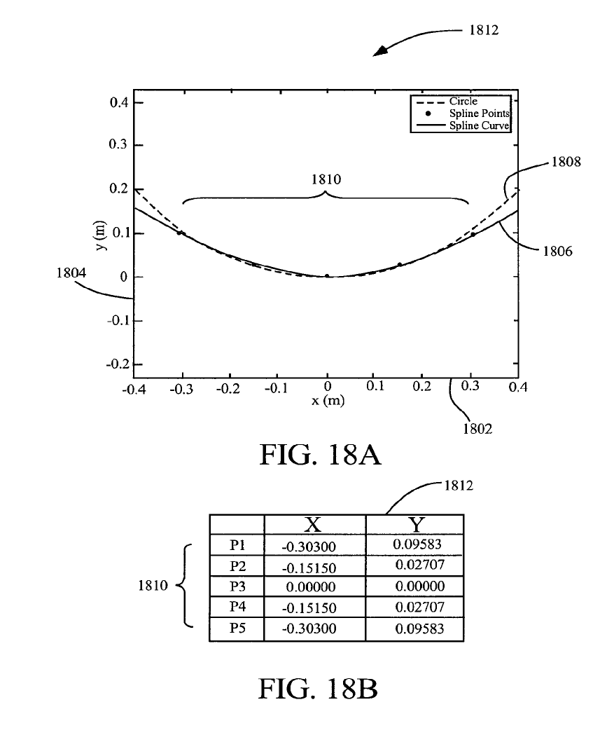

It should be understood that the cross sectional views of the apparatus in the above embodiment and the subsequent embodiments of the present invention may be cross sections for both two dimensional (point focusing) and one dimensional (line/trough focusing) light directing systems. For example, light bending elements utilized in two dimensional focusing are generally dish shaped while light bending elements for one dimensional focusing are generally trough shaped. Further, environmental simulation software, such as Light Tools (version 6.0 by Optical Research Associates), may be utilized to determine the shape of the light bending elements throughout this specification. In one embodiment, the environmental simulation software is a ray-tracing environmental simulation software which generates a ray trace diagram for various configurations of light bending elements. The environmental simulation software will be discussed further with respect to FIG. 18).

In addition, the target for a two dimensional light directing system is a point target while the target for a one dimensional light directing system is a line target. For example, a point target may comprise a photovoltaic cell, while a line target may comprise a light energy (solar energy) absorbing pipe enveloping a flowable material such as a working fluid. In addition the light rays (incoming and reflected light rays), light source, and the light energy may refer to solar rays, the sun, and solar energy. As mentioned previously, other waves may be utilized with the various embodiments of the present invention, such as water, impact, compression, radar, and sound waves.

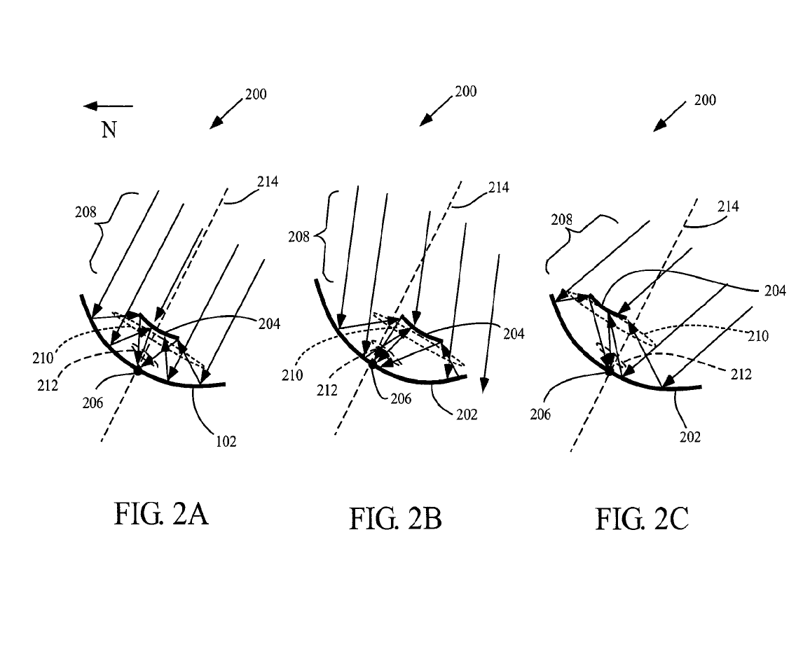

Referring next to FIGS. 2A, 2B, and 2C, cross sectional views of an apparatus 200 during equinox, summer, and winter lighting conditions in accordance with another embodiment of the present invention is illustrated comprising a primary light bending element 202, secondary light bending element 204, target 206, incoming light rays 208, primary directed light rays 210, secondary directed light rays 212, and primary axis 214 of the primary light bending element 202.

FIGS. 2A, 2B, and 2C exemplifies one embodiment of the apparatus 200 where the primary light bending element 202 and the target 206 remains stationary over time while the secondary light bending element 204 moves over time. Movement of the secondary light bending element 204 relative to the primary light bending element 202 and the target 206 is a function of the various angle of incidences of the incoming light rays 208, primary directed light rays 210, and the secondary directed light rays 212.

FIG. 2A exemplifies one embodiment of the apparatus 200 during equinox lighting conditions. The primary light bending element 202 is located at about 30 degree N latitude and the primary axis 214 of the primary light bending element 202 is roughly tilted at 30 degrees from the vertical to direct light incoming At equinox, the incoming light rays 208 from a light source strike the light bending element 202 at an incident angle of about 30 degrees from the vertical (or parallel with the primary axis 214). It should be appreciated that the primary light bending element may be located at any latitude and therefore the primary light bending element may be tilted at any axis angle to correspond to equinox lighting conditions. In addition, the primary light bending element may be tilted at any axis angle to correspond with solstice conditions or to prioritize winter or summer conditions, or morning or evening light. Further, the tilting of the primary light bending element may be further modified to account for the slope of the surface which the primary light bending element rests or for various weather conditions.

The primary light bending element 202 is disposed in the light path of the light energy between a light source and the target 206. In one embodiment, the light source may be the sun, light energy may be solar energy, and the light path represents the path of the solar rays to the target. The incoming light rays 208 travel to the primary light bending element 202 from a light source. The secondary light bending element 204 is also disposed in the light path of the light energy between the light source and the target 206. In some embodiments, the secondary light bending element 204 is disposed in the light path of the light energy between the primary light bending element 202 and the target 206. In other embodiments, the primary light bending element 202 is disposed in the light path of the light energy between the secondary light bending element 204 and the target 206. Primary directed light rays 210 leave the primary light bending element 202 and travel to the secondary light bending element 204. The secondary directed light rays 212 leave the secondary light bending element 204 and travel to the target 206. The target 206 is positioned at the area which the secondary light bending element 204 focuses the secondary reflected light rays 212.

The primary light bending element 202 receives the incoming light rays 208 from a light source. As the incoming light rays 208 interface with the primary light bending element 202, the primary light bending element 202 directs the incoming light rays 208. In one embodiment, the primary light bending element 202 is shaped to direct the incoming light rays 208 to the target 206 through the secondary light bending element 204. The secondary light bending element 204 receives the primary directed light rays 210 from the primary light bending element 202, the primary directed light rays 210 are then directed as secondary directed light rays 212 to the target 206. The secondary light bending element 204 is shaped to direct the primary reflected light rays 210 to the target 206.

In one embodiment, the primary and the secondary light bending elements 202, 204 are reflective minors shaped to direct the incoming light rays 208 and the primary directed light rays 210 to the target 206. The target 206 may be a light energy absorbing element such as a photovoltaic cell (or array) or an enclosed working fluid. The primary and secondary light bending elements 202, 204 reflects the incoming light rays 208 and the primary directed light rays 210 as secondary directed light rays 212 to the target 206. The reflected incoming light rays are exemplified as the primary directed light rays 208 and the reflected primary directed light rays 208 are exemplified as secondary directed light rays 210. The secondary light bending element 204 is shaped to direct the primary reflected light rays 210 to the target 206. In one embodiment, the shape of the secondary light bending element 204 is determined by the location of the secondary light bending element 204 to the coma of the primary light bending element 202. As illustrated in FIGS. 2A, 2B, and 2C, the secondary light bending element 204 is in a convex shape to the primary light bending element 202 since the secondary light bending element 204 lies between the primary bending element 202 and the coma of the primary light bending element 202.

FIG. 2B exemplifies one embodiment of the apparatus 200 during summer lighting conditions. As illustrated, the incident angle of the incoming light rays 208 strike the primary light bending element 202 at about 6.5 degrees from the vertical (rather than the 30 degrees illustrated in FIG. 2A) while the primary light bending element 202 remains tilted on its primary axis 214. The incoming light rays 208 strike the primary light bending element 202 and are directed as primary directed light rays 210 towards the secondary light bending element 204. The primary directed light rays 210 are diverted to the target as secondary directed light rays 212. Since the incident angle of the incoming light rays 208 is closer to the vertical, the area of focus of the primary directed light rays 210 shifts and the primary directed light rays 210 travel towards the right of the primary light bending element 202. The shift of the area of focus of the primary directed light rays 210 results in a shift of the area of focus of the secondary directed light rays 212. The secondary light bending element 204 then moves to the area which the primary light bending element 202 focuses the primary directed light rays 210. As a result, the secondary light bending element 204 may alter the area of focus of the secondary directed light rays 212 to the location of the target 206. Since the secondary light bending element 204 is mobile, this allows the apparatus 200 to collect a greater amount of light energy (solar energy) than if the primary light bending element 202, secondary light bending element 204, and target remained stationary. In addition to improving the efficiency of collecting light energy, the various embodiments of the present invention may also improve the concentration power of the light energy. In particular, the light energy may be focused to a much smaller target than previous configurations for collecting light energy. Movement of the secondary light bending element 204 may include rotation of the secondary light bending element 204 along the center axis of the secondary light bending element 204.

FIG. 2C illustrates one embodiment of the apparatus 200 during winter lighting conditions. As illustrated, the incident angle of the incoming light rays 208, as the incoming light rays 208 strike the primary light bending element 202, shifts farther away from the vertical than illustrated with respect to FIGS. 2A and 2B during equinox and summer lighting conditions. As a result, the area of focus of the primary directed light rays 210 and the secondary directed light rays 212 shifts. The secondary light bending element 204 moves to the area which the primary light bending element 202 focuses the primary directed light rays 210. As a result, the secondary light bending element 204 may alter the area of focus of the secondary directed light rays 212 to the location of the target 206.

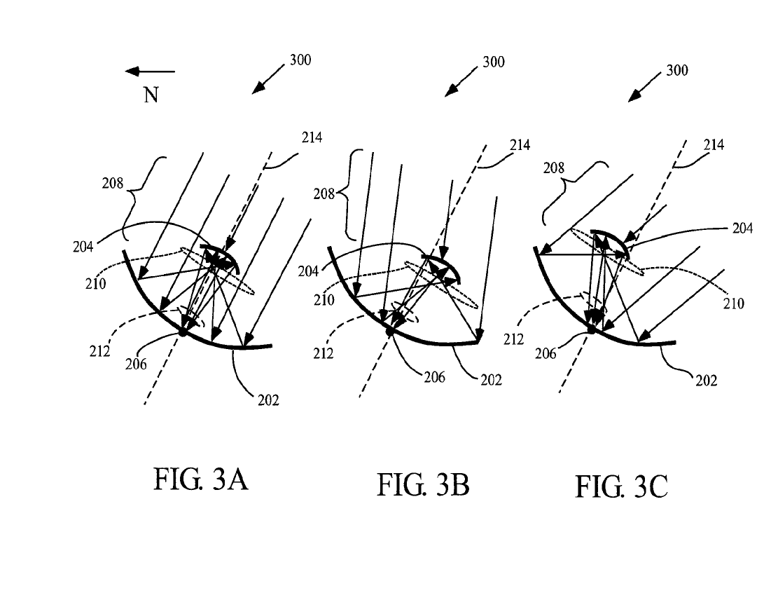

Referring next to FIGS. 3A, 3B, and 3C, cross sectional views of an apparatus 300 during equinox, summer, and winter lighting conditions in accordance with another embodiment of the present invention is illustrated comprising a primary light bending element 202, secondary light bending element 204, target 206, incoming light rays 208, primary directed light rays 210, secondary directed light rays 212, and primary axis 214 of the primary light bending element 202.

The various elements of FIGS. 3A, 3B, and 3C are structured and function similar to the various elements of FIGS. 2A, 2B and 2C. However, as is illustrated in FIGS. 3A, 3B and 3C, the shape of the secondary light bending element 204 is in a concave shape to the primary bending element 202. As mentioned above, the secondary light bending element 204 is shaped to direct the primary reflected light rays 210 to the target 206 and the shape of the secondary light bending element 204 is determined by the location of the secondary light bending element 204 to the coma of the primary light bending element 202. Since the coma of the primary light bending element 202 lies between the primary light bending element 202 and the secondary light bending element 204, the secondary light bending element 204 has a concave shape to the primary light bending element 202.

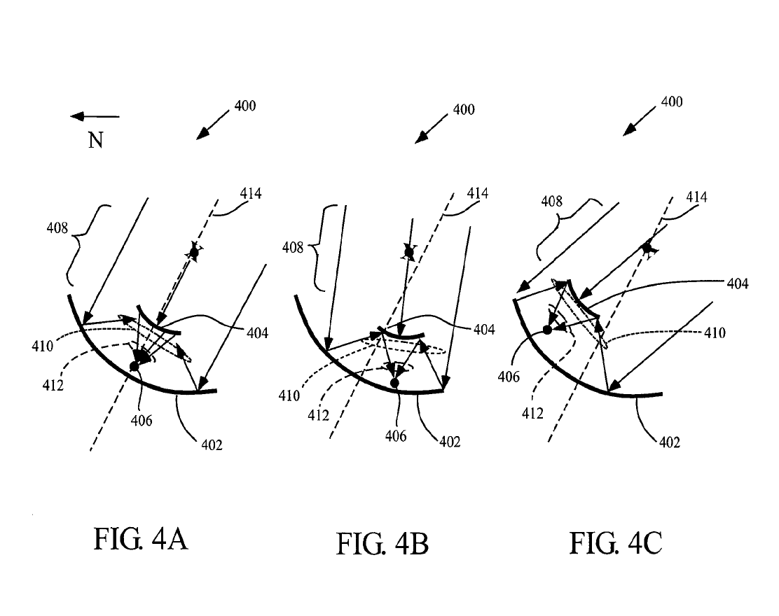

Referring next to FIGS. 4A, 4B, and 4C, cross sectional views of an apparatus 400 during equinox, summer, and winter lighting conditions in accordance with another embodiment of the present invention is illustrated comprising a primary light bending element 402, secondary light bending element 404, target 406, incoming light rays 408, primary directed light rays 410, secondary directed light rays 412, and primary axis 414 of the primary light bending element 402. It should be noted that the various elements which comprise FIGS. 4A, 4B, and 4C are similar in structure and function as the various elements of FIGS. 2A, 2B, and 2C; however, the target 406 is not stationary and moves along with the secondary light bending element 404.

FIGS. 4A, 4B, and 4C exemplifies one embodiment of the apparatus 400 where the primary light bending element 402 remains stationary over time while the secondary light bending element 404 and the target 406 are locked together and move together over time. Movement of the secondary light bending element 404 and the target 406 relative to the primary light bending element 402 is a function of the various angle of incidences of the incoming light rays 408, primary directed light rays 410, the secondary directed light rays 412, and the primary axis 414.

FIG. 4A exemplifies one embodiment of the apparatus 400 during equinox lighting conditions. The primary light bending element 402 is located at about 30 degree N latitude and the primary axis 414 of the primary light bending element 402 is roughly tilted at 30 degrees from the vertical to direct light incoming At equinox, the incoming light rays 408 from a light source strike the light bending element 402 at an incident angle of about 30 degrees from the vertical (or parallel with the primary axis 414). It should be appreciated that the primary light bending element may be located at any latitude and therefore the primary light bending element may be tilted at any axis angle to correspond to equinox lighting conditions. In addition, the primary light bending element may be tilted at any axis angle to correspond with solstice conditions or to prioritize winter or summer conditions, or morning or evening light. Further, the tilting of the primary light bending element may be further modified to account for the slope of the surface which the primary light bending element rests or for various weather conditions.

The primary light bending element 402 is disposed in the light path of the light energy between a light source and the target 406. In one embodiment, the light source may be the sun, light energy may be solar energy, and the light path represents the path of the solar rays to the target. The incoming light rays 408 travel to the primary light bending element 402 from a light source. The secondary light bending element 404 is also disposed in the light path of the light energy between the light source and the target 406. In some embodiments, the secondary light bending element 404 is disposed in the light path of the light energy between the primary light bending element 402 and the target 406. In other embodiments, the primary light bending element 402 is disposed in the light path of the light energy between the secondary light bending element 404 and the target 406. Primary directed light rays 410 leave the primary light bending element 402 and travel to the secondary light bending element 404. The secondary directed light rays 412 leave the secondary light bending element 404 and travel to the target 406. The target 406 is positioned at the area which the secondary light bending element 404 focuses the secondary directed light rays 412.

The primary light bending element 402 receives the incoming light rays 408 from a light source. As the incoming light rays 408 interface with the primary light bending element 402, the primary light bending element 402 directs the incoming light rays 408. In one embodiment, the primary light bending element 402 is shaped to direct the incoming light rays 408 to the target 406 through the secondary light bending element 404. The secondary light bending element 404 receives the primary directed light rays 410 from the primary light bending element 402, the primary directed light rays 410 are then directed as secondary directed light rays 412 to the target 406. The secondary light bending element 404 is shaped to direct the primary reflected light rays 410 to the target 406.

In one embodiment, the primary and the secondary light bending elements 402, 404 are reflective minors shaped to direct the incoming light rays 408 and the primary directed light rays 410 to the target 406. The target 406 may be a light energy absorbing element such as a photovoltaic array or an enclosed working fluid. The primary and secondary light bending elements 402, 404 reflects the incoming light rays 408 and the primary directed light rays 410 as secondary directed light rays 412 to the target 406. The reflected incoming light rays are exemplified as the primary directed light rays 408 and the reflected primary directed light rays 408 are exemplified as secondary directed light rays 410. The secondary light bending element 404 is convexly shaped to direct the primary reflected light rays 410 to the target 406. In one embodiment, the shape of the secondary light bending element 404 is determined by the location of the secondary light bending element 404 to the coma of the primary light bending element 402. As illustrated in FIGS. 4A, 4B, and 4C, the secondary light bending element 404 is in a convex shape to the primary light bending element 402 since the secondary light bending element 404 lies between the primary bending element 402 and the coma of the primary light bending element 402. It should be appreciated that the secondary light bending element 404 may be concavely shaped to the target primary light bending element 402, as illustrated in FIGS. 3A, 3B, and 3C, when the coma lies between the primary and the secondary light bending elements 402, 404.

FIG. 4B exemplifies one embodiment of the apparatus 400 during summer lighting conditions. As illustrated, the incident angle of the incoming light rays 408 strike the primary light bending element 402 at about 6.5 degrees from the vertical (rather than the 30 degrees illustrated in FIG. 4A) while the primary light bending element remains tilted on its primary axis 414. The incoming light rays 408 strike the primary light bending element 402 and are directed as primary directed light rays 410 towards the secondary light bending element 404. The primary directed light rays 410 are diverted to the target as secondary directed light rays 412. Since the incident angle of the incoming light rays 408 is closer to the vertical, the area of focus of the primary directed light rays 410 shifts and the primary directed light rays 410 travel towards the right of the primary light bending element 402. The shift of the area of focus of the primary directed light rays 410 results in a shift of the area of focus of the secondary directed light rays 412. The secondary light bending element 404 then moves to the area which the primary light bending element 402 focuses the primary directed light rays 410. As a result, the target 406 moves along with the secondary light bending element 402. The target 406 moves to the location of the area of focus of the secondary directed light rays 412. Since the secondary light bending element 404 and the target 406 is mobile, this allows the apparatus 400 to collect a greater amount of light energy (solar energy) than if the primary light bending element 402, secondary light bending element 404, and target 406 remained stationary. In addition to improving the efficiency of collecting light energy, the various embodiments of the present invention may also improve the concentration power of the light energy. In particular, the light energy may be focused to a much smaller target than previous configurations for collecting light energy.

FIG. 4C illustrates one embodiment of the apparatus 400 during winter lighting conditions. As illustrated, the incident angle of the incoming light rays 408, as the incoming light rays 408 strike the primary light bending element 402, shifts farther away from the vertical than illustrated with respect to FIGS. 4A and 4B during equinox and summer lighting conditions. As a result, the area of focus of the primary directed light rays 410 and the secondary directed light rays 412 shifts. The secondary light bending element 404 moves to the area which the primary light bending element 402 focuses the primary directed light rays 410. As a result, the target 406 moves along with the secondary light bending element 402. The target 406 moves to the location of the area of focus of the secondary directed light rays 412.

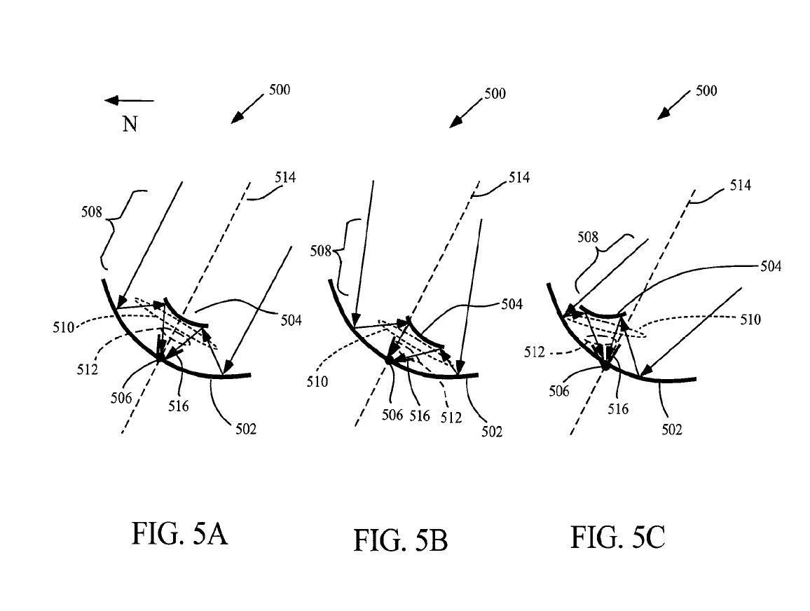

Referring next to FIGS. 5A, 5B, and 5C, cross sectional views of an apparatus during equinox, summer, and winter lighting conditions in accordance with another embodiment of the present invention are illustrated comprising a primary light bending element 502, secondary light bending element 504, target 506, incoming light rays 508, primary directed light rays 510, secondary directed light rays 512, primary axis 514 of the primary light bending element 502, and third light bending element 516.

FIGS. 5A, 5B, and 5C exemplifies one embodiment of the apparatus 500 where the primary light bending element 502 and the target 506 remains stationary over time while the secondary light bending element 504 moves over time. In addition, movement of the third light bending element 516 comprises rotation of the third light bending element 516 along the center axis of the third light bending element 516 such that the rotation of the third light bending element 516 tracks the movement of the secondary light bending element 502. Movement of the secondary light bending element 504 relative to the primary light bending element 502 and the target 506 is a function of the various angle of incidences of the incoming light rays 508, primary directed light rays 510, and the secondary directed light rays 512. It should be noted that the various elements which comprise FIGS. 5A, 5B, and 5C are similar in structure and function as the various elements of FIGS. 2A, 2B, and 2C, however, the FIGS. 5A, 5B and 5C illustrate an additional light bending element 516 utilized to further direct light energy to the target 506.

FIG. 5A exemplifies one embodiment of the apparatus 500 during equinox lighting conditions. The primary light bending element 502 is located at about 30 degree N latitude and the primary axis 514 of the primary light bending element 502 is roughly tilted at 30 degrees from the vertical to direct light incoming At equinox, the incoming light rays 508 from a light source strike the light bending element 502 at an incident angle of about 30 degrees from the vertical (or parallel with the primary axis 514). It should be appreciated that the primary light bending element may be located at any latitude and therefore the primary light bending element may be tilted at any axis angle to correspond to equinox lighting conditions. In addition, the primary light bending element may be tilted at any axis angle to correspond with solstice conditions or to prioritize winter or summer conditions, or morning or evening light. Further, the tilting of the primary light bending element may be further modified to account for the slope of the surface which the primary light bending element rests or for various weather conditions.

The primary light bending element 502 is disposed in the light path of the light energy between a light source and the target 506. In one embodiment, the light source may be the sun, light energy may be solar energy, and the light path represents the path of the solar rays to the target. The incoming light rays 508 travel to the primary light bending element 502 from a light source. The secondary light bending element 504 and the third light bending element 516 is also disposed in the light path of the light energy between the light source and the target 506. In some embodiments, the secondary light bending element 504 is disposed in the light path of the light energy between the primary light bending element 502 and the target 506. In other embodiments, the primary light bending element 502 is disposed in the light path of the light energy between the secondary light bending element 504 and the target 506. Primary directed light rays 510 leave the primary light bending element 502 and travel to the secondary light bending element 504. The secondary directed light rays 512 leave the secondary light bending element 504 and travel to the target 506. However, the third light bending element 516 may receive the secondary directed light rays 512 prior to the secondary directed light rays 512 reaching the target 506. When this occurs, the secondary directed light rays 512 leave the third light bending element 516 and travel to the target 506. The target 506 is positioned at the area which the secondary light bending element 504 focuses the secondary directed light rays 512.

The primary light bending element 502 receives the incoming light rays 508 from a light source. As the incoming light rays 508 interface with the primary light bending element 502, the primary light bending element 502 directs the incoming light rays 508. In one embodiment, the primary light bending element 502 is shaped to direct the incoming light rays 508 to the target 506 through the secondary light bending element 504 and the third light bending element 516. The secondary light bending element 504 receives the primary directed light rays 210 from the primary light bending element 502, the primary directed light rays 510 are then directed as secondary directed light rays 512 to the target 506. The secondary light bending element 504 is shaped to direct the primary directed light rays 210 to the target 206. At times, the third light bending element 516 receives the secondary directed light rays 512 and then directs the secondary directed light rays 512 to the target 506.

In one embodiment, the primary, secondary, and third light bending elements 502, 504, 516 are reflective mirrors shaped to reflect the incoming light rays 508, the primary directed light rays 510, and the secondary directed light rays 512 to the target 206. The target 506 may be a light energy absorbing element such as a photovoltaic array or an enclosed working fluid. The primary, secondary, and third light bending elements 502, 504, 516 reflect the incoming light rays 508, the primary directed light rays 510 as secondary directed light rays 512 to the target 506. The reflected incoming light rays are exemplified as the primary directed light rays 508 and the reflected primary directed light rays 508 are exemplified as secondary directed light rays 510. The secondary light bending element 504 is shaped to direct the primary reflected light rays 510 to the target 506. In one embodiment, the shape of the secondary light bending element 504 is determined by the location of the secondary light bending element 504 to the coma of the primary light bending element 502.

As illustrated in FIGS. 5A, 5B, and 5C, the secondary light bending element 504 is in a convex shape to the primary light bending element 502 since the secondary light bending element 504 lies between the primary bending element 502 and the coma of the primary light bending element 502. It should be appreciated that the secondary light bending element 504 may be concavely shaped to the target primary light bending element 502, as illustrated in FIGS. 3A, 3B, and 3C, when the coma lies between the primary and the secondary light bending elements 502, 504. In one embodiment, the third light bending element 516 comprises a tertiary mirror to further direct light energy to the target 506.

FIG. 5B exemplifies one embodiment of the apparatus 500 during summer lighting conditions. As illustrated, the incident angle of the incoming light rays 508 strike the primary light bending element 502 at about 6.5 degrees from the vertical (rather than the 30 degrees illustrated in FIG. 5A) while the primary light bending element 502 remains tilted on its primary axis 514. The incoming light rays 508 strike the primary light bending element 502 and are directed as primary directed light rays 510 towards the secondary light bending element 504. The primary directed light rays 510 are diverted to the target as secondary directed light rays 512. Since the incident angle of the incoming light rays 508 is closer to the vertical, the area of focus of the primary directed light rays 510 shifts and the primary directed light rays 510 travel towards the right of the primary light bending element 502. The shift of the area of focus of the primary directed light rays 510 results in a shift of the area of focus of the secondary directed light rays 512. The secondary light bending element 504 then moves to the area which the primary light bending element 502 focuses the primary directed light rays 510. As a result, the secondary light bending element 504 may alter the area of focus of the secondary directed light rays 512 to the location of the target 506. In addition, movement of the third light bending element 516 comprises rotation of the third light bending element 516 along the center axis of the third light bending element 516 such that the rotation of the third light bending element 516 tracks the movement of the secondary light bending element 502. Since the secondary light bending element 504 is mobile and the third light bending element 516 may rotate, this allows the apparatus 500 to collect a greater amount of light energy (solar energy) than if the primary light bending element 502, secondary light bending element 504, third light bending element 516, and the target 506 remained stationary. In addition to improving the efficiency of collecting light energy, the various embodiments of the present invention may also improve the concentration power of the light energy. In particular, the light energy may be focused to a much smaller target than previous configurations for collecting light energy. Movement of the secondary light bending element 504 may include rotation of the secondary light bending element 504 along the center axis of the secondary light bending element 504.

FIG. 5C illustrates one embodiment of the apparatus 500 during winter lighting conditions. As illustrated, the incident angle of the incoming light rays 508, as the incoming light rays 508 strike the primary light bending element 502, shifts farther away from the vertical than illustrated with respect to FIGS. 5A and 5B during equinox and summer lighting conditions. As a result, the area of focus of the primary directed light rays 510 and the secondary directed light rays 512 shifts. The secondary light bending element 504 moves to the area which the primary light bending element 502 focuses the primary directed light rays 510. As a result, the secondary light bending element 504 may alter the area of focus of the secondary directed light rays 512 to the location of the target 506. In addition, movement of the third light bending element 516 comprises rotation of the third light bending element 516 along the center axis of the third light bending element 516 such that the rotation of the third light bending element 516 tracks the movement of the secondary light bending element 502.

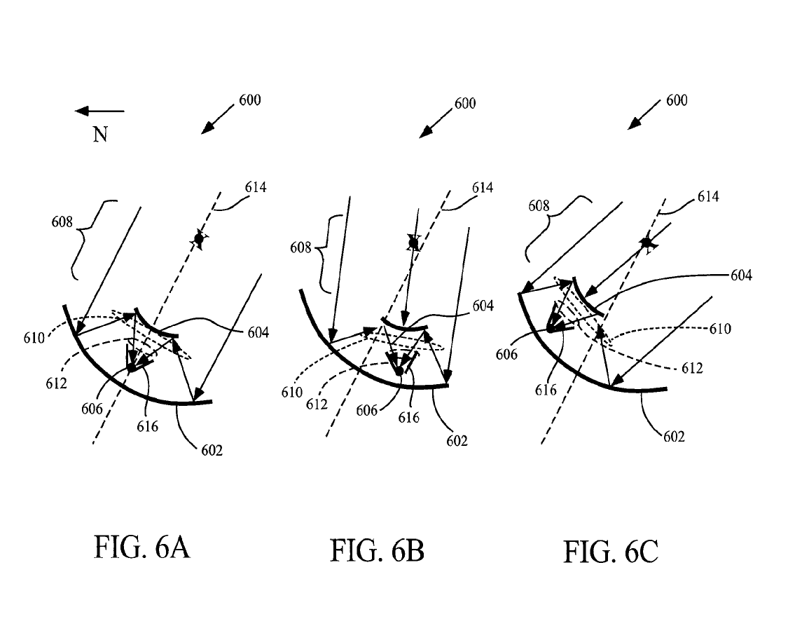

Referring next to FIGS. 6A, 6B, and 6C, cross sectional views of an apparatus during equinox, summer, and winter lighting conditions in accordance with another embodiment of the present invention is illustrated comprising a primary light bending element 602, secondary light bending element 604, target 606, incoming light rays 608, primary directed light rays 610, secondary directed light rays 612, primary axis 614 of the primary light bending element 602, and a third light bending element 616. It should be noted that the various elements which comprise FIGS. 6A, 6B, and 6C are similar in structure and function as the various elements of FIGS. 5A, 5B, and 5C; however, the target 606 is not stationary and moves along with the secondary light bending element 604. In addition, the third light bending element 616 also moves along with the target 606 and the secondary light bending element 604.

FIGS. 6A, 6B, and 6C exemplifies one embodiment of the apparatus 600 where the primary light bending element 602 remains stationary over time while the secondary light bending element 604, the third light bending element 616, and the target 606 are locked together and move together over time. Movement of the secondary light bending element 604, the third light bending element 616, and the target 606 relative to the primary light bending element 602 is a function of the various angle of incidences of the incoming light rays 608, primary directed light rays 610, and the secondary directed light rays 612. It should be noted that the various elements which comprise FIGS. 6A, 6B, and 6C are similar in structure and function as the various elements of FIGS. 4A, 4B, and 4C, however, the FIGS. 6A, 6B and 6C illustrate an additional light bending element 616 utilized to further direct light energy to the target 606.

FIG. 6A exemplifies one embodiment of the apparatus 600 during equinox lighting conditions. The primary light bending element 602 is located at about 30 degree N latitude and the primary axis 614 of the primary light bending element 602 is roughly tilted at 30 degrees from the vertical to direct light incoming At equinox, the incoming light rays 608 from a light source strike the light bending element 602 at an incident angle of about 30 degrees from the vertical (or parallel with the primary axis 614). It should be appreciated that the primary light bending element may be located at any latitude and therefore the primary light bending element may be tilted at any axis angle to correspond to equinox lighting conditions. In addition, the primary light bending element may be tilted at any axis angle to correspond with solstice conditions or to prioritize winter or summer conditions, or morning or evening light. Further, the tilting of the primary light bending element may be further modified to account for the slope of the surface which the primary light bending element rests or for various weather conditions.

The primary light bending element 602 is disposed in the light path of the light energy between a light source and the target 606. In one embodiment, the light source may be the sun, light energy may be solar energy, and the light path represents the path of the solar rays to the target. The incoming light rays 608 travel to the primary light bending element 602 from a light source. The secondary light bending element 604 is also disposed in the light path of the light energy between the light source and the target 606. In some embodiments, the secondary light bending element 604 is disposed in the light path of the light energy between the primary light bending element 602 and the target 606. In other embodiments, the primary light bending element 602 is disposed in the light path of the light energy between the secondary light bending element 604 and the target 606. Primary directed light rays 610 leave the primary light bending element 602 and travel to the secondary light bending element 604. The secondary directed light rays 612 leave the secondary light bending element 604 and travel to the target 606. However, the third light bending element 616 may receive the secondary directed light rays 612 prior to the secondary directed light rays 612 reaching the target 606. When this occurs, the secondary directed light rays 612 leave the third light bending element 616 and travel to the target 606. The target 606 is positioned at the area which the secondary light bending element 604 focuses the secondary directed light rays 612.

The primary light bending element 602 receives the incoming light rays 608 from a light source. As the incoming light rays 608 interface with the primary light bending element 602, the primary light bending element 602 directs the incoming light rays 608. In one embodiment, the primary light bending element 602 is shaped to direct the incoming light rays 608 to the target 606 through the secondary light bending element 604 and the third light directing element 616. The secondary light bending element 604 receives the primary directed light rays 610 from the primary light bending element 602, the primary directed light rays 610 are then directed as secondary directed light rays 612 to the target 606. The secondary light bending element 604 is shaped to direct the primary reflected light rays 610 to the target 606. At times, the third light bending element 616 receives the secondary directed light rays 612 and then directs the secondary directed light rays 612 to the target 606.

In one embodiment, the primary, secondary, and third light bending elements 602, 604, and 616 are reflective minors shaped to direct the incoming light rays 608, the primary directed light rays 610, and the secondary directed light rays 612 to the target 606. The target 606 may be a light energy absorbing element such as a photovoltaic array or an enclosed working fluid. The primary, secondary, and third light bending elements 602, 604, and 615 reflect the incoming light rays 608 and the primary directed light rays 610 as secondary directed light rays 612 to the target 606. The reflected incoming light rays 608 are exemplified as the primary directed light rays 610 and the reflected primary directed light rays are exemplified as secondary directed light rays 612. The secondary light bending element 604 is convexly shaped to direct the primary reflected light rays 610 to the target 606. In one embodiment, the shape of the secondary light bending element 604 is determined by the location of the secondary light bending element 604 to the coma of the primary light bending element 602.

As illustrated in FIGS. 6A, 6B, and 6C, the secondary light bending element 604 is in a convex shape to the primary light bending element 602 since the secondary light bending element 604 lies between the primary bending element 602 and the coma of the primary light bending element 602. It should be appreciated that the secondary light bending element 604 may be concavely shaped to the target primary light bending element 602, as illustrated in FIGS. 3A, 3B, and 3C, when the coma lies between the primary and the secondary light bending elements 602, 604. In one embodiment, the third light bending element 616 comprises a tertiary mirror to further direct light energy to the target 606.

FIG. 6B exemplifies one embodiment of the apparatus 600 during summer lighting conditions. As illustrated, the incident angle of the incoming light rays 608 strike the primary light bending element 602 at about 6.5 degrees from the vertical (rather than the 30 degrees illustrated in FIG. 6A) while the primary light bending element remains tilted on its primary axis 614. The incoming light rays 608 strike the primary light bending element 602 and are directed as primary directed light rays 610 towards the secondary light bending element 604. The primary directed light rays 610 are diverted to the target as secondary directed light rays 612. Since the incident angle of the incoming light rays 608 is closer to the vertical, the area of focus of the primary directed light rays 610 shifts and the primary directed light rays 610 travel towards the right of the primary light bending element 602. The shift of the area of focus of the primary directed light rays 610 results in a shift of the area of focus of the secondary directed light rays 612. The secondary light bending element 604 then moves to the area which the primary light bending element 602 focuses the primary directed light rays 610. As a result, the target 606 and the third light bending element 616 moves along with the secondary light bending element 602. The target 606 and the third light bending element 616 move to the location of the area of focus of the secondary directed light rays 612. Since the secondary light bending element 604, the third light bending element 616, and the target 606 are mobile, this allows the apparatus 600 to collect a greater amount of light energy (solar energy) than if the primary light bending element 602, secondary light bending element 604, the third light bending element 616, and the target 606 remained stationary. In addition to improving the efficiency of collecting light energy, the various embodiments of the present invention may also improve the concentration power of the light energy. In particular, the light energy may be focused to a much smaller target than previous configurations for collecting light energy.

FIG. 6C illustrates one embodiment of the apparatus 600 during winter lighting conditions. As illustrated, the incident angle of the incoming light rays 608, as the incoming light rays 608 strike the primary light bending element 602, shifts farther away from the vertical than illustrated with respect to FIGS. 6A and 6B during equinox and summer lighting conditions. As a result, the area of focus of the primary directed light rays 610 and the secondary directed light rays 612 shifts. The secondary light bending element 604 moves to the area which the primary light bending element 602 focuses the primary directed light rays 610. As a result, the target 606 and the third light bending element 616 move along with the secondary light bending element 604. The target 606 moves to the location of the area of focus of the secondary directed light rays 612.

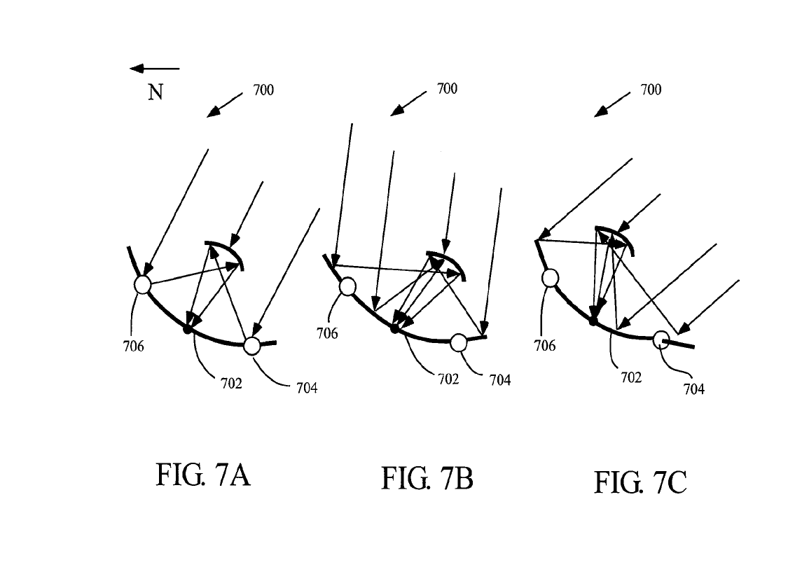

FIGS. 7A, 7B, and 7C cross sectional views of an apparatus 700 during equinox, summer, and winter lighting conditions in accordance with another embodiment of the present invention illustrating a light bending element 702 and bend points 704, 706.

The apparatus 700 of FIGS. 7A, 7B, and 7C may be any of the herein described embodiments of the present invention. However, the light bending element 702 comprises a flexible material. In other embodiments, any of the light bending elements mentioned may be made of a flexible material. In another embodiment, the light bending element 702 is comprised of a flexible reflective material. The bend points 704, 706 are disposed within the light bending element 702 and exemplify the flexible movement and deferment of the light bending element 702. It should be appreciated that the flexible movement of the light bending element 702 is not limited to two bend points 704, 706 and may have any number of bend points.

Subtle movement of the edges of the light bending elements (in particular when the light bending elements are mirrors or other reflective devices) may provide considerable improvement in the ability to direct light energy and subsequent rays of light. In one embodiment, flexible movement may be achieved through a hinged light bending element. In another embodiment, flexible movement may be achieved by utilizing the inherent flexibility of the material which comprises the light bending element itself. Typically, focusing of sunlight is not optimal for sunlight which strike a circular mirror or for sunlight which is not parallel to the primary axis of a light bending element. For the previous cases, the rays which strike the outermost portion of the light bending element typically deviate the most from the area of focus. By utilizing additional flexible movement, the shape of the light bending element may be further improved to increase the collection of solar energy.

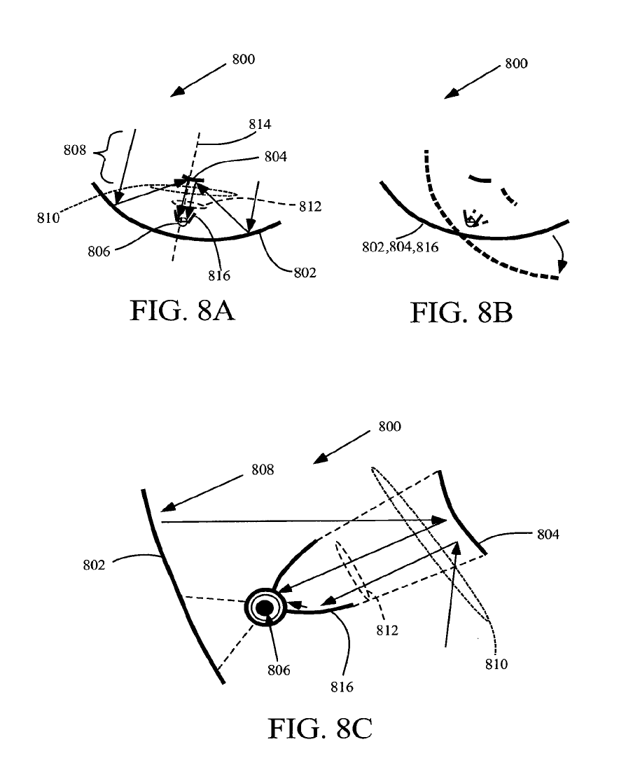

Referring next to FIGS. 8A, 8B, and 8C, cross sectional views of an apparatus is shown in accordance with another embodiment of the present invention. FIG. 8B provides a cross sectional view illustrating the movement of the apparatus of FIG. 8A while FIG. 8C provides a close up view of the apparatus of FIG. 8A. FIGS. 8A, 8B and 8C provide cross sectional views of an apparatus 800, wherein the apparatus comprises a primary light bending element 802, secondary light bending element 804, target 806, incoming light rays 808, primary directed light rays 810, secondary directed light rays 812, primary axis 814 of the primary light bending element 802, and a third light bending element 816. It should be noted that the various elements which comprise FIGS. 8A, 8B, and 8C are similar in structure and function as the various elements of FIGS. 6A, 6B, and 6C, however, the target 806 is stationary while the primary light bending element 802 and moves along with the secondary light bending element 804. In addition, the third light bending element 816 also moves along with the secondary light bending element 804.

FIGS. 8A, 8B, and 8C exemplifies one embodiment of the apparatus 800 where the target 806 remains stationary over time while primary light bending element 802, the secondary light bending element 804, the third light bending element 816, are locked together and move together over time. Movement of the primary light bending element 802, the secondary light bending element 804, and the third light bending element 816 relative to the target 806 is a function of the various angle of incidences of the incoming light rays 808, primary directed light rays 810, and the secondary directed light rays 812.

The primary light bending element 802 is disposed in the light path of the light energy between a light source and the target 806. In one embodiment, the light source may be the sun, light energy may be solar energy, and the light path represents the path of the solar rays to the target. The incoming light rays 808 travel to the primary light bending element 802 from a light source. The secondary light bending element 804 is also disposed in the light path of the light energy between the light source and the target 806. In some embodiments, the secondary light bending element 804 is disposed in the light path of the light energy between the primary light bending element 802 and the target 806. In other embodiments, the primary light bending element 802 is disposed in the light path of the light energy between the secondary light bending element 804 and the target 806. Primary directed light rays 810 leave the primary light bending element 802 and travel to the secondary light bending element 804. The secondary directed light rays 812 leave the secondary light bending element 804 and travel to the target 806. However, the third light bending element 816 may receive the secondary directed light rays 812 prior to the secondary directed light rays 812 reaching the target 806. When this occurs, the secondary directed light rays 812 leave the third light bending element 816 and travel to the target 806.The target 806 is positioned at the area which the secondary light bending element 804 focuses the secondary directed light rays 812.

The primary light bending element 802 receives the incoming light rays 808 from a light source. As the incoming light rays 808 interface with the primary light bending element 802, the primary light bending element 802 directs the incoming light rays 808. In one embodiment, the primary light bending element 802 is shaped to direct the incoming light rays 808 to the target 806 through the secondary light bending element 804 and the third light directing element 816. The secondary light bending element 804 receives the primary directed light rays 810 from the primary light bending element 802, the primary directed light rays 810 are then directed as secondary directed light rays 812 to the target 806. The secondary light bending element 804 is shaped to direct the primary directed light rays 810 to the target 806. At times, the third light bending element 816 receives the secondary directed light rays 812 and then directs the secondary directed light rays 812 to the target 806.

In one embodiment, the primary, secondary, and third light bending elements 802, 804, 816 are reflective mirrors shaped to direct the incoming light rays 808, the primary directed light rays 810, and the secondary directed light rays 812 to the target 806. The target 806 may be a light energy absorbing element such as a photovoltaic array or an enclosed working fluid. The primary, secondary, and third light bending elements 802, 804, 816 reflect the incoming light rays 808 and the primary directed light rays 810 as secondary directed light rays 812 to the target 806 (this may be depicted clearer with respect to FIG. 8C). The reflected incoming light rays are exemplified as the primary directed light rays 808 and the reflected primary directed light rays 808 are exemplified as secondary directed light rays 810. The secondary light bending element 804 is convexly shaped to direct the primary reflected light rays 810 to the target 806. In one embodiment, the shape of the secondary light bending element 804 is determined by the location of the secondary light bending element 804 to the coma of the primary light bending element 802.

As illustrated in FIGS. 8A, 8B, and 8C, the secondary light bending element 804 is in a convex shape to the primary light bending element 802 since the secondary light bending element 804 lies between the primary bending element 802 and the coma of the primary light bending element 802. It should be appreciated that the secondary light bending element 804 may be concavely shaped to the target primary light bending element 802, as illustrated in FIGS. 3A, 3B, and 3C, when the coma lies between the primary and the secondary light bending elements 802, 804. In one embodiment, the third light bending element 816 comprises a tertiary mirror to further direct light energy to the target 806.

FIG. 8B illustrates the movement of the apparatus 800 as incoming light rays 808 are received at the primary light bending element 802 at different angles of incidence with respect to the vertical. As mentioned above, the primary, secondary, and third light bending elements 802, 804, 816 are locked together and move together over time. As the incoming light rays 808 strike the primary light bending element 802, the primary, secondary, and third light bending elements 802, 804, 816 rotate about the primary axis 814 such that the incoming light rays 808 are parallel with the primary axis 816. FIG. 8B illustrates the joint movement of the primary, secondary, and third light bending elements 802, 804, 816. The target 806 remains stationary as the primary, secondary, and third light bending elements 802, 804, 816 move from a first position, illustrated in solid lines, to a second position, illustrated in dashed lines.

FIG. 8C illustrates a close up view of the apparatus 800 of FIG. 8A. As illustrated, the primary directed light rays 810 may be directed to the target 806 directly as secondary directed light rays 812, or the secondary directed light rays 812 may interface with the third light bending element 816 before the secondary directed light rays 812 (and therefore the incoming light rays 808) is received at the target 806. In some embodiments, the third light bending element 816 comprises a tertiary mirror which directs the secondary directed light rays 812 towards the target 806.

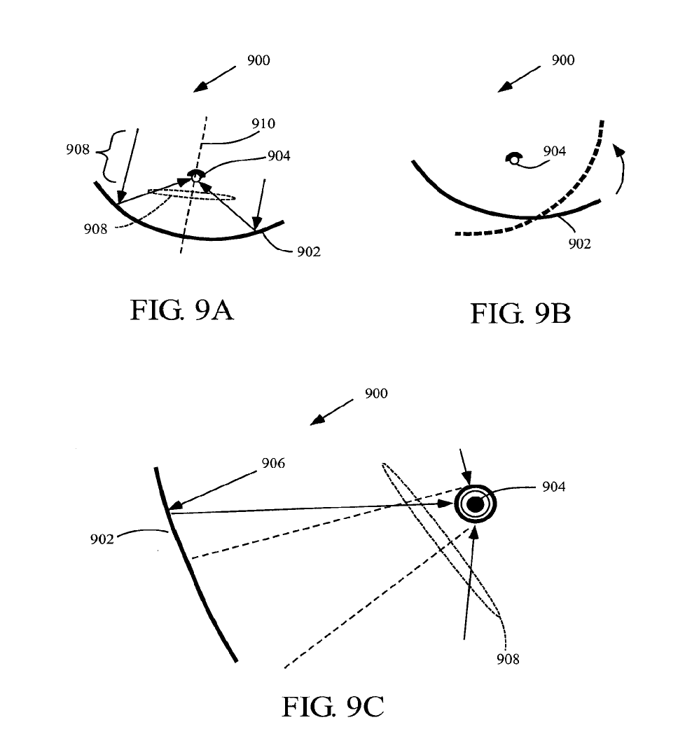

Referring next to FIGS. 9A, 9B, and 9C, cross sectional views of an apparatus is shown in accordance with another embodiment of the present invention. FIG. 9B provides a cross sectional view illustrating the movement of the apparatus of FIG. 9A while FIG. 9C provides a close up view of the apparatus of FIG. 9A. FIGS. 9A, 9B and 9C provide cross sectional views of an apparatus 900, wherein the apparatus comprises a primary light bending element 902, target 904, incoming light rays 906, primary directed light rays 908, and a primary axis 910 of the primary light bending element 902. In another embodiment, the apparatus further includes a second light bending element disposed immediately next to the target 904 which functions similar to the third light bending element of FIGS. 5, 6 and 8. It should be noted that the various elements which comprise FIGS. 9A, 9B, and 9C are similar in structure and function as the various elements of FIGS. 1A, 1B, and 1C; however, the target 904 is stationary while the primary light bending element 902 rotates. In addition, when the apparatus comprises a second light bending element, the primary light bending element 902 moves along with the second light bending element (such as a tertiary minor).

FIGS. 9A, 9B, and 9C exemplifies one embodiment of the apparatus 900 where the target 906 remains stationary over time while primary light bending element 902 is locked in rigid assembly with the target 904. In some embodiments, the target 906 remains stationary over time while the primary light bending element 902 and a third light bending element is locked together and move together over time. Movement of the primary light bending element 902 relative to the target 906 is a function of at least the angle of incidence of the incoming light rays 906 and the primary directed light rays 908.

The primary light bending element 902 is disposed in the light path of the light energy between a light source and the target 904. In one embodiment, the light source may be the sun, light energy may be solar energy, and the light path represents the path of the solar rays to the target. The incoming light rays 906 travel to the primary light bending element 902 from a light source. Primary directed light rays 906 leave the primary light bending element 902 and travel to the target 904. In one embodiment, the target 904 is positioned at the area which the primary light bending element 902 focuses the primary directed light rays 908.

The primary light bending element 902 receives the incoming light rays 906 from a light source. As the incoming light rays 906 interface with the primary light bending element 902, the primary light bending element 902 directs the incoming light rays 906. In one embodiment, the primary light bending element 902 is shaped to direct the incoming light rays 906 directly to the target 904. In another embodiment, the primary light bending element 902 utilizes a second light bending element to direct the primary directed light rays 908 to the target 904.

In one embodiment, the primary light bending element 902is a reflective minor shaped to direct the incoming light rays 906 and the primary directed light rays 908to the target 904. The target 904 may be a light energy absorbing element such as a photovoltaic array or an enclosed working fluid. The primary light bending element 902 reflects the incoming light rays 906 as primary directed light rays 908 to the target 904. The reflected incoming light rays are exemplified as the primary directed light rays 908. In some embodiment utilizing a third light bending element, the third light bending element comprises a rotating minor or a tertiary mirror.

FIG. 9B illustrates the movement of the apparatus 900 as incoming light rays 908 are received at the primary light bending element 902 at different angles of incidence with respect to the vertical. As the incoming light rays 906 strike the primary light bending element 902, the light bending elements 902 rotates about the primary axis 910 such that the incoming light rays 906 are parallel with the primary axis 910. The target 906 remains stationary as the primary light bending elements 902 move from a first position, illustrated in solid lines, to a second position, illustrated in dashed lines. FIG. 9C illustrates a close up view of the apparatus 900 of FIG. 9A. As mentioned above, the primary light bending elements of FIGS. 8 and 9 may be collapsible, as detailed with regards to FIGS. 7A, 7B, and 7C, allowing the portion of the primary mirror in the shade to collapse via a hinge in order to save room. In addition, the primary minor may collapse due to the flexible properties of the material comprising the primary minor.

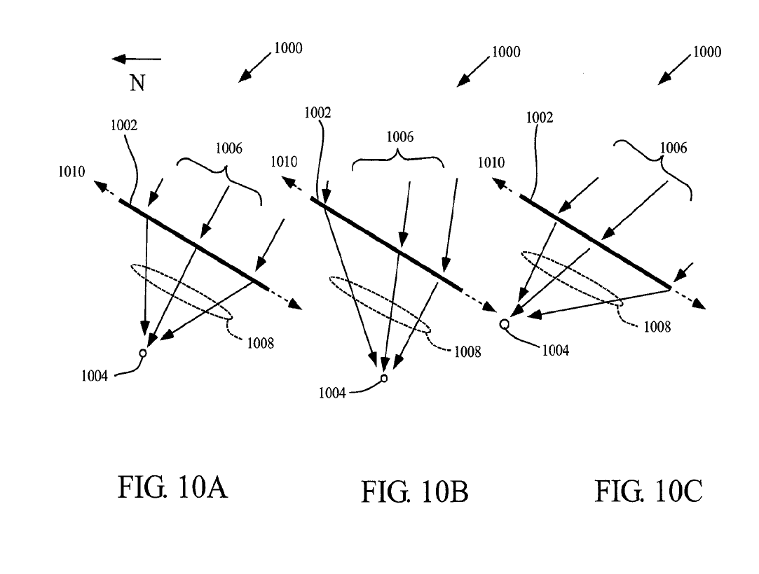

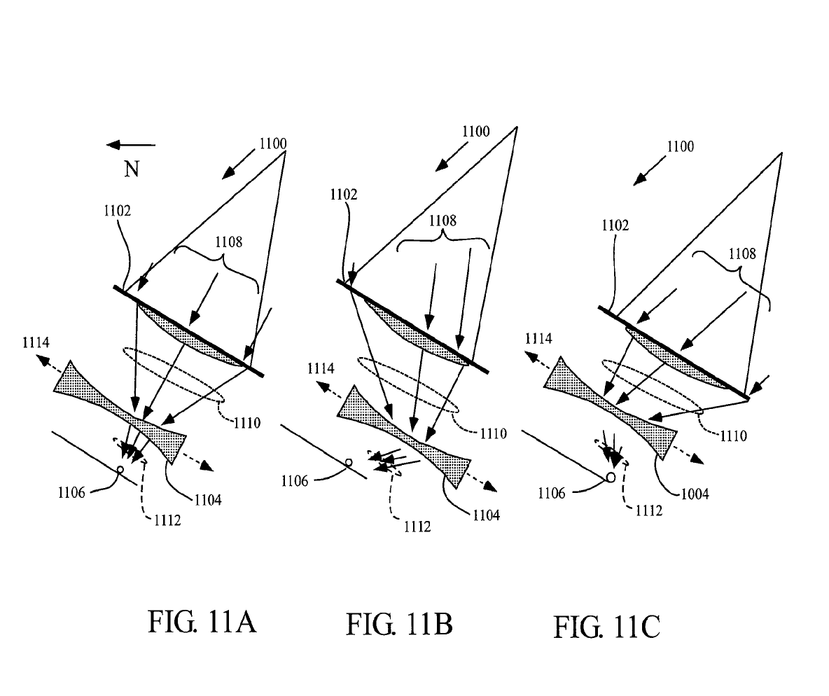

Referring next to FIGS. 10A, 10B, and 10C, cross sectional views of an apparatus 1000 during equinox, summer, and winter lighting conditions in accordance with one embodiment of the present invention are illustrated comprising light bending element 1002, target 1004, incoming light rays 1006, directed light rays 1008, and primary axis 1010 of the light bending element 1002 (the primary axis 1010 may also be referred to as the direction of movement 1010). It is noted that the various elements comprising FIGS. 10A, 10B, and 10C are similar in function and structure to the various elements comprising FIGS. 1A, 1B, and 1C, however, the light bending element 1002 directs the incoming light rays 1006 through the light bending element 1002 itself, and directs the incoming light rays 1006 to the target 1004 as primary directed light rays 1008.

FIG. 10A exemplifies one embodiment of the apparatus 1000 during equinox lighting conditions. The light bending element is located at about 30 degree N latitude and the primary axis 1010 of the light bending element 1002 is roughly tilted at 30 degrees from the vertical to direct light incoming. At equinox, the incoming light rays 1006 from a light source strike the light bending element 1002 at an incident angle of about 30 degrees (or about orthogonal with the primary axis 110). It should be appreciated that the light bending element may be located at any latitude and therefore the primary light bending element may be tilted at any axis angle to correspond to equinox lighting conditions. In addition, the primary light bending element may be tilted at any axis angle to correspond with solstice conditions or to prioritize winter or summer conditions, or morning or evening light. Further, the tilting of the primary light bending element may be further modified to account for the slope of the surface which the primary light bending element rests or for various weather conditions.

The light bending element 1002 is disposed in the light path of the light energy between a light source and the target 1004. In one embodiment, the light source may be the sun, light energy may be solar energy, and the light path represents the path of the solar rays to the target 1004. The incoming light rays 1006 travel to the light bending element 1002 from a light source. Then the directed light rays 1008 leave the light bending element 1002 and travel to the target 1004 as primary directed light rays 1008. The target 1004 is positioned at the area which the light bending element 1002 focuses the directed light rays 1008.

The light bending element 1002 receives the incoming light rays 1006 from a light source. As the incoming light rays 1006 interface with the light bending element 1002, the light bending element 1002 directs the incoming light rays 1006. In one embodiment, the light bending element 1002 is shaped to direct the incoming light rays 1006 to the target 1004. The directed incoming light rays 1006 are exemplified as directed light rays 1008, the directed light rays 1008 then travels to the target 1004.

In one embodiment, the light bending element 1002 is a lens, such as a Fresnel lens or a solid lens, shaped to direct the incoming light rays 1006 to the target 1004 through refraction. In one embodiment, the light bending element 1002 is shaped to direct both parallel and oblique incoming light rays 1006. The target 1004 may be a light energy absorbing element such as a photovoltaic array or an enclosed working fluid. The light bending element 1002 then directs the incoming light rays 1006 towards the target 1004. The refracted incoming light rays are exemplified as the directed light rays 1008.

FIG. 10B exemplifies one embodiment of the apparatus 1000 during summer lighting conditions. As illustrated, the incident angle of the incoming light rays 1006 strike the light bending element 1002 at about 6.5 degrees from the vertical (rather than the 30 degrees illustrated in FIG. 10A) while the light bending element remains oriented on the primary axis 1010. The incoming light rays 1006 strike the light bending element 1002 and is directed as directed light rays 1008 towards the target 1006. Since the incident angle of the incoming light rays 1006 are closer to the vertical, the area of focus of the reflected light rays 1008 shifts and the directed light rays 1008 travel towards the right of its previous position. The target 1002 then moves to the area which the light bending element 1002 focuses the directed light rays 1008. As illustrated, the direction of movement of the target 1002 is parallel with the primary axis 1010. However, it should be appreciated that the target 1002 may also move perpendicular with the primary axis 1010. Since the target 1004 is mobile, this allows the apparatus 1000 to collect a greater amount of light energy (solar energy) than if the target 1004 and the light bending element 1002 remained stationary. In addition to improving the efficiency of collecting light energy, the various embodiments of the present invention may also improve the concentration power of the light energy. In particular, the light energy may be focused to a much smaller target than previous configurations for collecting light energy.

FIG. 10C illustrates one embodiment of the apparatus 1000 during winter lighting conditions. As illustrated, the incident angle of the incoming light rays 1006, as the incoming light rays 1006 strike the light bending element 1002, shifts farther away from the vertical than illustrated with respect to FIGS. 10A and 10B during equinox and summer lighting conditions. As a result, the area of focus of the directed light rays 1008 shifts towards the left of the location of the area of focus during equinox lighting conditions. The target 1002 then moves to the area which the light bending element 1002 remains stationary and focuses the directed light rays 1008. In another embodiment of the present invention, the target 1004 remains stationary while the light bending element 1002 moves such that the target 1004 is in the area of focus of the directed light rays 1008. In one embodiment, movement of the light bending element 1002 includes movement along the primary axis 1010. However, it should be appreciated that the movement of the light bending element 1002 may comprise movement perpendicular to the primary axis 1010. In another embodiment, the light bending element 1002 and the target 1004 are locked together and both the light bending element 1002 and the target 1004 move such that the target 1004 is in the area of focus of the directed light rays 1008. It should be appreciated the movement the primary bending element 1002 or the target 1004 along or perpendicular to the primary axis 1010 may further correspond to movement along or perpendicular to the primary plane, in the case of dish geometry, where the primary axis 1010 is a cross-sectional view of the primary plane.

Referring next to FIGS. 11A, 11B, and 11C, cross sectional views of an apparatus during equinox, summer, and winter lighting conditions in accordance with one embodiment of the present invention are illustrated comprising a primary light bending element 1102, secondary light bending element 1104, target 1106, incoming light rays 1108, primary directed light rays 1110, secondary directed light rays 1112, and primary axis 1114 (the primary axis 1114 may also be referred to as the direction of movement 1114). It is noted that the various elements comprising FIGS. 11A, 11B, and 11C are similar in function and structure to the various elements comprising FIGS. 2A, 2B, and 2C, however, the primary and secondary light bending elements 1102, 1104 illustrate respectively directing the incoming light rays 1108 and the primary directed light rays 1106 through the primary and secondary light bending elements 1102, 1104 themselves. The primary directed light rays 1110 are directed to the target as secondary directed light rays 1112.

FIGS. 11A, 11B, and 11C exemplify one embodiment of the apparatus 1100 where the primary light bending element 1102 and the target 1106 remain stationary over time while the secondary light bending element 1104 moves over time. Movement of the secondary light bending element 1104 relative to the primary light bending element 1102 and the target 1106 is a function of the at least one of the angle of incidences of the incoming light rays 1108, primary directed light rays 1110, and the secondary directed light rays 1112. However, in another embodiment the primary light bending element 1102 also moves over time to further focus the light energy to the target 1106.

FIG. 11A exemplifies one embodiment of the apparatus 1100 during equinox lighting conditions. The primary light bending element 1102 is located at about 30 degree N latitude and the primary axis 1114 of the primary light bending element 1102 and is roughly oriented to 30 degrees from the vertical to direct light incoming In addition, the secondary light bending element 1104 is roughly oriented with the primary axis 1114. At equinox, the incoming light rays 1108 from a light source strike the primary light bending element 1102 at an incident angle of about 30 degrees from the vertical (or about orthogonal with the primary axis 1114). It should be appreciated that the primary light bending element may be located at any latitude and therefore the primary light bending element may be tilted at any axis angle to correspond to equinox lighting conditions. In addition, the primary light bending element may be tilted at any axis angle to correspond with solstice conditions or to prioritize winter or summer conditions, or morning or evening light. Further, the tilting of the primary light bending element may be further modified to account for the slope of the surface which the primary light bending element rests or for various weather conditions.

The primary light bending element 1102 is disposed in the light path of the light energy between a light source and the target 1106. In one embodiment, the light source may be the sun, light energy may be solar energy, and the light path represents the path of the solar rays to the target 1106. The incoming light rays 1108 travel to the primary light bending element 1102 from a light source. The secondary light bending element 1104 is also disposed in the light path of the light energy between the light source and the target 1106. In some embodiments, the secondary light bending element 1104 is disposed in the light path of the light energy between the primary light bending element 1102 and the target 1106. In other embodiments, the primary light bending element 1102 is disposed in the light path of the light energy between the secondary light bending element 1104 and the target 1106. Primary directed light rays 1110 leave the primary light bending element 1102 and travel to the secondary light bending element 1104. The secondary directed light rays 1112 leave the secondary light bending element 1104 and travel to the target 1106. The target 1106 is positioned at the area which the secondary light bending element 1104 focuses the secondary reflected light rays 1112.

The primary light bending element 1102 receives the incoming light rays 1108 from a light source. As the incoming light rays 1108 interface with the primary light bending element 1102, the primary light bending element 1102 directs the incoming light rays 1108. In one embodiment, the primary light bending element 1102 is shaped to direct the incoming light rays 1108 to the target 1106 through the secondary light bending element 1104. The secondary light bending element 1104 receives the primary directed light rays 1110 from the primary light bending element 1102, the primary directed light rays 1110 are then directed as secondary directed light rays 1112 to the target 1106. The secondary light bending element 1104 is shaped to direct the primary reflected light rays 1110 to the target 1106.

In one embodiment, the primary and the secondary light bending elements 1102, 1104 are lenses, such as Fresnel lenses, shaped to direct the incoming light rays 1108 and the primary directed light rays 1110 to the target 1106. In one embodiment, the primary and secondary light bending elements 1102, 1104 are shaped to direct both parallel and oblique incoming light rays. The target 1106 may be a light energy absorbing element such as a photovoltaic array or an enclosed working fluid. The primary and secondary light bending elements 1102, 1104 directs the incoming light rays 1108 and the primary directed light rays 1110 as secondary directed light rays 1112 to the target 1106. The secondary light bending element 1104 is shaped to direct the primary reflected light rays 1110 to the target 1106. primary and secondary light bending elements 1102, 1104 direct the incoming light rays 1108 and the primary directed light rays 1110 by bending the incoming light rays 1108 and the primary directed light rays 1106 through the primary and secondary light bending elements 1102, 1104 themselves (as is typical of lenses). The primary directed light rays 1110 are directed to the target as secondary directed light rays 1112.

FIG. 11B exemplifies one embodiment of the apparatus 1100 during summer lighting conditions. As illustrated, the incident angle of the incoming light rays 1108 strike the primary light bending element 1102 at about 6.5 degrees from the vertical (rather than the 30 degrees illustrated in FIG. 11A) while the primary light bending element remains oriented with the primary axis 1114. The incoming light rays 1108 strike the primary light bending element 1102 and are directed as primary directed light rays 1110 towards the secondary light bending element 1104. The primary directed light rays 1110 are diverted to the target 1106 as secondary directed light rays 1112. Since the incident angle of the incoming light rays 1108 is closer to the vertical, the area of focus of the primary directed light rays 1110 shifts and the primary directed light rays 1110 shift accordingly The shift of the area of focus of the primary directed light rays 1110 results in a shift of the area of focus of the secondary directed light rays 1112. The secondary light bending element 1104 then moves such that the primary light bending element 1102 focuses the primary directed light rays 1110 to the target 1106. As a result, the secondary light bending element 1104 may alter the area of focus of the secondary directed light rays 1112 to the location of the target 1106. Since the secondary light bending element 1104 is mobile, this allows the apparatus 1100 to collect a greater amount of light energy (solar energy) than if the primary light bending element 1102, secondary light bending element 1104, and target remained stationary. In addition to improving the efficiency of collecting light energy, the various embodiments of the present invention may also improve the concentration power of the light energy. In particular, the light energy may be focused to a much smaller target than previous configurations for collecting light energy. Movement of the primary and secondary light bending element 1104, 1106 may include rotation of the primary and secondary light bending element 1104, 1106 in addition to movement in all three dimensions (x, y, and z).

FIG. 11C illustrates one embodiment of the apparatus 1100 during winter lighting conditions. As illustrated, the incident angle of the incoming light rays 1108, as the incoming light rays 1108 strike the primary light bending element 1102, shifts farther away from the vertical than illustrated with respect to FIGS. 11A and 11B during equinox and summer lighting conditions. As a result, the area of focus of the primary directed light rays 1110 and the secondary directed light rays 1112 shifts. The secondary light bending element 1104 moves to the area which the primary light bending element 1102 focuses the primary directed light rays 1110. As a result, the secondary light bending element 1104 may alter the area of focus of the secondary directed light rays 1112 to the location of the target 1106.

In one embodiment, the primary and secondary light bending elements move such that the target remains stationary and in the area of the focused light. In a further embodiment, the target moves to the area of focus while the primary or secondary light bending elements remain stationary. In another embodiment, the target moves to the area of focus while both the primary and the secondary light bending elements remain stationary. Movement of the primary light bending element 1102, secondary light bending element 1104 and target 1106 may be parallel with primary axis 1114. However, it should be appreciated that movement of the primary light bending element 1102, secondary light bending element 1104 and target 1106 may also comprise movement perpendicular to the primary axis 1114. It should be appreciated the movement of the primary light bending element 1102, secondary light bending element 1104 or the target 1106 along or perpendicular to the primary axis 1114 may further correspond to movement along or perpendicular to the primary plane, in the case of dish geometry, where the primary axis 1114 is a cross-sectional view of the primary plane.

The several embodiments of the present invention utilize a given number of light bending elements and a target. However, it should be appreciated that a greater number of light bending elements may be utilized than what has been described, and any number of targets may be utilized to collect the light energy. In addition, several embodiments of the invention may utilize both minors and lenses. It should also be appreciated that each of the primary, secondary, and third light bending elements may also be referred as a light bending element, a further light bending element, and an additional light bending element and that the use of “primary,” “secondary,” and “third” are not meant to imply an order for the light bending elements.

The embodiments described herein specifically refer to light waves/rays and solar energy. Although, it should be understood that the embodiments of the present invention may be utilized with many different types of waves which propagate through a medium at various wavelengths and frequencies with corresponding wave energy. A few examples include sound waves, compression waves, ocean waves, water waves and radar waves,

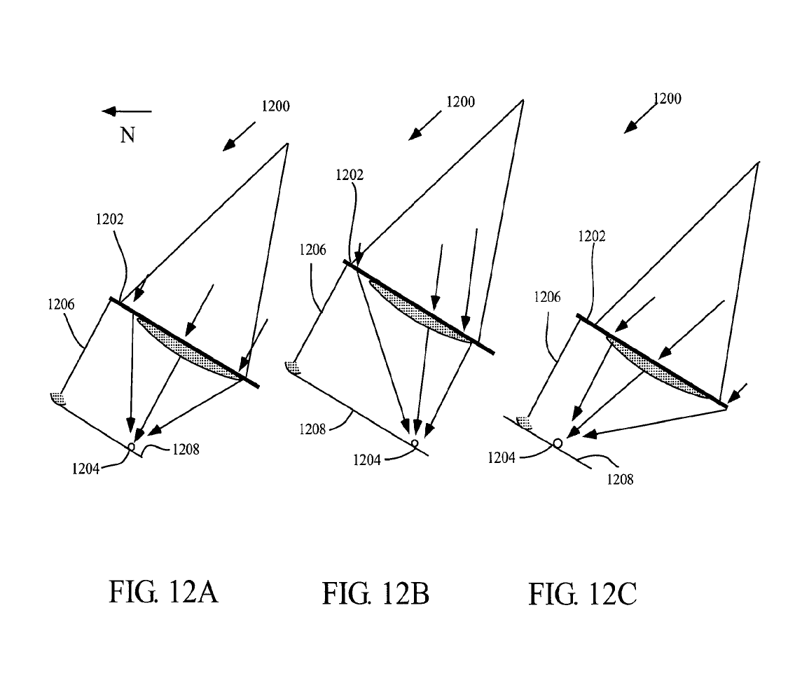

Referring next to FIGS. 12A, 12B, and 12C, cross sectional views of an apparatus 1200 utilizing a follower in accordance with embodiment of the present invention is shown which comprises a light bending element 1202, target 1204, a follower 1206, and surface 1208.

The light bending element 1202 directs light energy to the target 1204. The follower 1206 is coupled to the light bending element 1202 and is disposed between the light bending element 1202 and the surface 1208. The target 1204 rests upon the surface 1208.

The light bending element 1202 and target 1204 functions as described above. The follower 1206 is comprised of a rigid material which controls the vertical distance between the light bending element 1202 and the surface 1208. As a result, the follower 1206 maintains a controllable tunable distance between the light bending element 1202 and the target 1204. In one embodiment, the follower 1206 further comprises a rounded cam. The portion of the follower 1206 closer to the target 1204 rides along the surface which the target 1204 rests upon, since the follower 1206 is of a rigid material, the follower is able to constantly tune the distance between the light bending element 1202 and the target 1204 regardless of the contour of the surface 1208. This is especially useful for preserving the integrity of the structure of the apparatus 1200. The surface 1208 may be of any contour. Since the surface may be of any contour, the surface 1208 may be utilized to control the tunable distance between the target 1204 and the light bending element 1202. In some embodiments, the surface may comprise multiple targets. It should be appreciated that any of the embodiments described herein may be utilized with the follower 1206 for maintaining a constant tunable distance between the light bending element and the surface 1208.

For example, the surface may have multiple targets disposed within the surface. As sunlight bends over time, the various light bending elements may be tracked over the surface to any of the multiple targets. The follower then allows the light bending elements to maintain a distance between the various light bending elements and the multiple targets such that the sunlight may be focused on the targets.

It should be appreciated that any embodiment discussed herein may also utilize the follower 1206 to maintain a constant tunable distance.

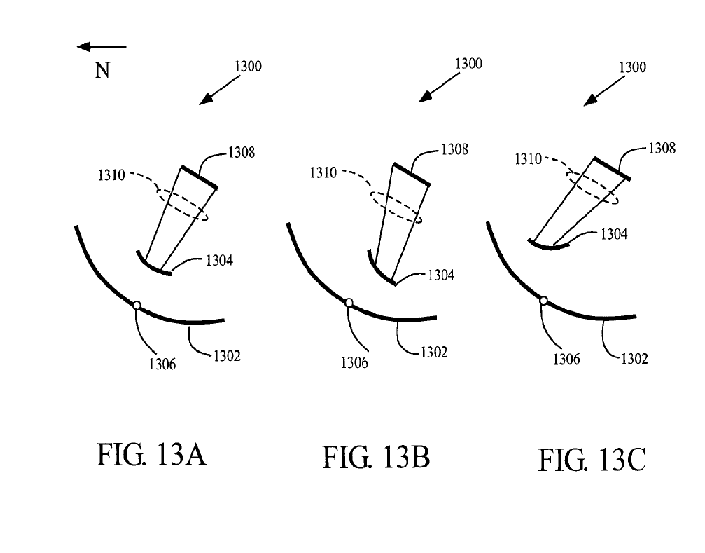

FIGS. 13A, 13B, and 13C are cross sectional views illustrating a support device of an apparatus 1300 in accordance with one embodiment of the present invention illustrating a primary light bending element 1302, secondary light bending element 1304, target 1306, support bar 1308 and handles 1310.

The primary and secondary light bending elements 1302 and the target 1306 function as discussed above (with particular reference to FIGS. 2A, 2B and 2C). The support bar 1308 is coupled to the secondary light bending element 1304 through handles 1310. The secondary light bending element 1304 is disposed between the support bar 1308 and the primary light bending element 1302.

The support bar 1308 may be utilized to provide control over the movement of the secondary light bending element 1304. The movement of the secondary light bending element 1304 (and other light bending elements discussed herein) include movement of position and pitch. The handles 1310 connecting the support bar 1308 to the secondary light bending element 1304 are comprised of a rigid material. Since the handles 1310 are comprised of a rigid material, as the position and pitch of the support bar 1308 is altered, then the position and pitch of the secondary light bending element is also altered. The arc of travel of the secondary light bending element 1304 is controlled by the length of the handles and the distance between the support bar 1308 and the center of curvature of the primary light bending element 1304. In addition, the pitch of the secondary light bending element 1304 may be further controlled by the length of the support bar 1308 relative to the distance between the handles 1310 at the secondary light bending element 1304.

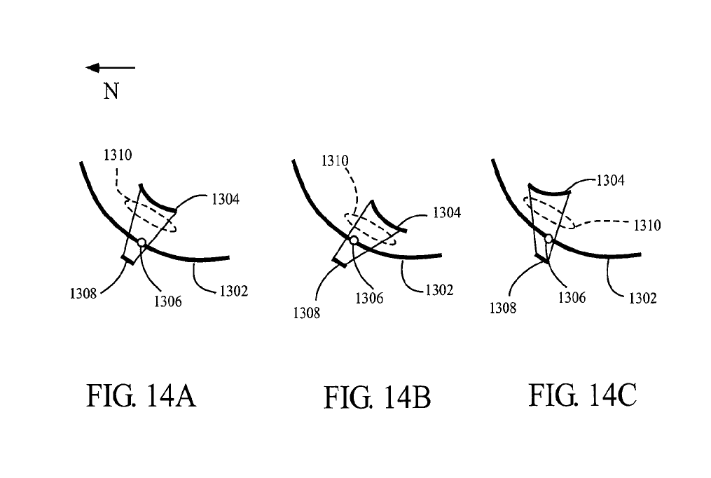

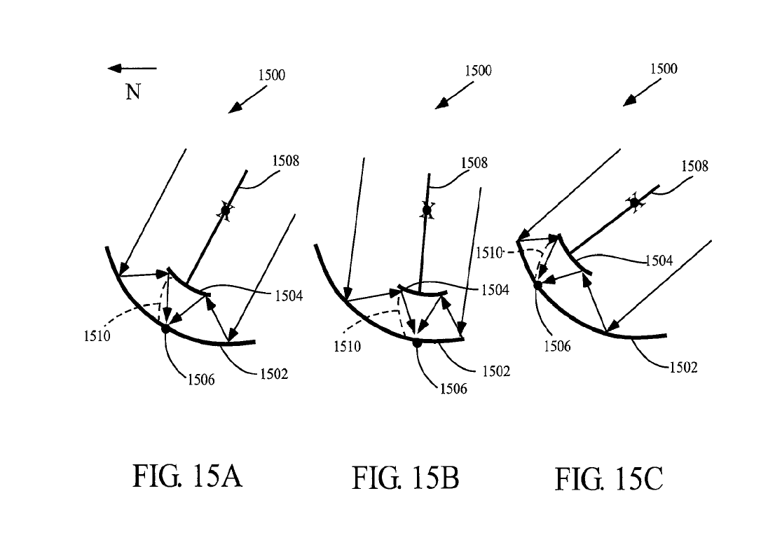

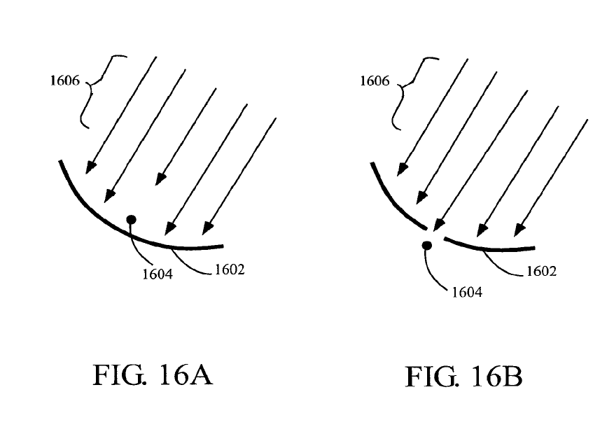

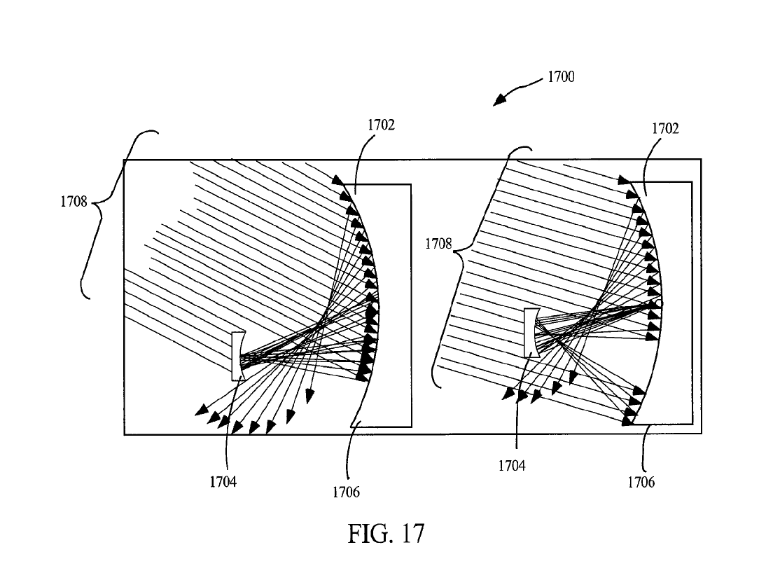

Referring next to FIGS. 14A, 14B, and 14C, cross sectional views illustrating a support component of an apparatus in accordance with one embodiment of the present invention is shown illustrating a primary light bending element 1302, secondary light bending element 1304, target 1306, support bar 1308 and handles 1310.

The elements of FIGS. 14A, 14B, and 14C function as above, however, the primary light bending element 1302 is disposed between the support bar 1308 and the secondary light bending element 1304.

It should be appreciated that any of the embodiments described herein may utilize the support bar 1308 as described above.

FIGS. 15A, 15B, and 15C are cross sectional views illustrating a support component of an apparatus 1500 in accordance with one embodiment of the present invention further comprising primary light bending element 1502, secondary light bending element 1504, target 1506, support rod 1508, and target support 1510.

The primary light bending element 1502, secondary light bending element 1504, and the target 1506 function as described with any of the embodiments described above (with particular reference to FIGS. 4A, 4B, 4C, 6A, 6B, and 6C). The support rod 1508 is coupled to the secondary light bending element 1504. The target support 1510 connects the secondary light bending element 1504 to the target 1506.

The support rod 1508 and the target support 1510 may be utilized to provide control over the movement of the secondary light bending element 1504 and the target 1506 (in some embodiments, the support rod 1508 and the target support 1510 also provide control of the third light bending element as described above). The support rod 1508 connects to the secondary light bending element 1504 and is comprised of a rigid material. The target support 1510 then connects the secondary light bending element 1504 to the target 1506 and is also comprised of a rigid material. In another embodiment, the target support 1510 may be connected to the third light bending element of FIGS. 6A, 6B, and 6C to provide the rigid support of target. Since the support rod 1508 and the target support 1510 are comprised of rigid materials, as the position of the support rod 1508 moves, the secondary light bending element 1504, target 1506, and target support 1510 also move. The secondary light bending element 1504, target 1506, and target support 1510 also maintain the same orientation with respect to each other as the support rod 1508 moves.

The support rod 1508 and the support bar described with respect to FIGS. 13A, 13B, 13C, 14A, 14B, and 14C may move through the use of mechanical or electrical devices, such as a motor. In addition, these support devices may also be moved manually.

Referring next to FIGS. 16A and 16B, cross sectional views illustrating positioning of a target in accordance with one embodiment of the present invention is illustrated comprising light bending element 1602, target 1604, and light rays 1606 from a light source.

The light bending element 1602, target 1604, and light rays 1606 function as described above. In FIG. 16A, the target 1604 may be positioned between the light source and the light bending element 1602 such that light rays 1606 are directed towards the target 1604. However, in FIG. 16B, the light bending element 1602 is positioned between the light source and the target 1604. In this case, the light bending element 1602 has an opening which allows the light rays 1606 to pass through the primary light bending element to the target 1604. The light bending element 1602 may be a reflective or refractive device, such as a mirror, or a lens.

Referring next to FIG. 17, is a diagram illustrating a simulation 1700 of an apparatus in accordance with one embodiment of the present invention comprising primary light bending element 1702, secondary light bending element 1704, and target 1706.

In particular, the simulation 1700 simulates the embodiment described with respect to FIGS. 3A, 3B, and 3C. The simulation 1700 may be utilized to determine the shape and size of the primary and secondary light bending elements 1702, 1704. The simulation 1700 models how the light rays 1708 interact with the primary light bending element 1702 and the secondary light bending element 1704 then displays a visual to a user. In particular, the simulation utilizes at what angle of incidence the light rays 1708 hits the primary light bending element 1702 and the secondary light bending element 1704 to determine the light path of the light rays 1708. An example of such a simulation would be Light Tools (version 6.0 by Optical Research Associates). The primary light bending element 1702 is generally simulated as a circular reflector since it is known how the focus moves for a circular reflector. The secondary light bending element 1704 is placed at the coma of the primary light bending element 1702. Depending one the input for the angle of incidence of the light rays, a formula calculates the direction of the light rays depending upon the shape of the light bending elements, the position of the light bending elements, and the angle of incidence of light rays upon the light bending elements.

The simulation of the left illustrates the results for light incidence of 23.5 degrees from the primary axis of the secondary light bending element 1704, the shape and the position of which is for an incident angle of 15 degrees. The simulation of the left illustrates the results for the same secondary light bending element with incoming light at an incident angle of 18 degrees.

FIG. 18A is a graphical illustration of a shape of an apparatus in accordance with one embodiment of the present invention comprising x-axis 1802. Y-axis 1804, light bending element shape 1806, circle shape 1808, and spline points 1810.

The x-axis 1802 and y-axis 1804 provide a distance meter for the given light bending element shape 1806 to illustrate the surface of curvature. In addition, the spline points 1810 are utilized to demonstrate the surface of curvature for the light bending element shape 1806. In particular, the FIG, 18A provides a graphical illustration of the light bending element shape 1806 of the light bending element of the simulation 1700 described above. As reference, the shape of a circle 1808 has also been graphically included to compare the shape of a circle 1808 to the shape of the light bending element 1806. FIG. 18B provides a table 1812 of the numerical values of the spline points 1810.

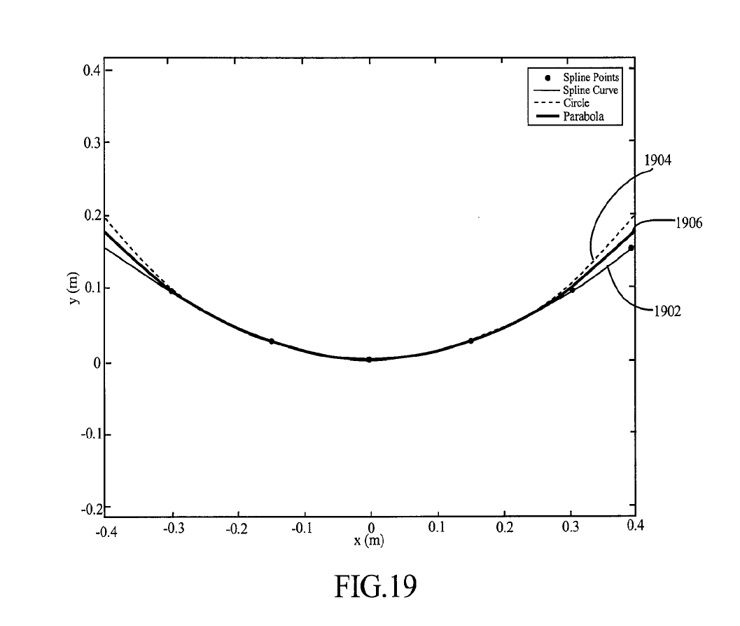

FIG. 19 is another graphical illustration of a shape of an apparatus in accordance with one embodiment of the present invention illustrating the light bending element shape 1902, circle shape 1904, and parabola shape 1906. FIG. 19 is similar to FIG. 18A, however, the shape of a parabola 1906 is illustrated to provide a further comparison to the shape of the light bending element 1902.

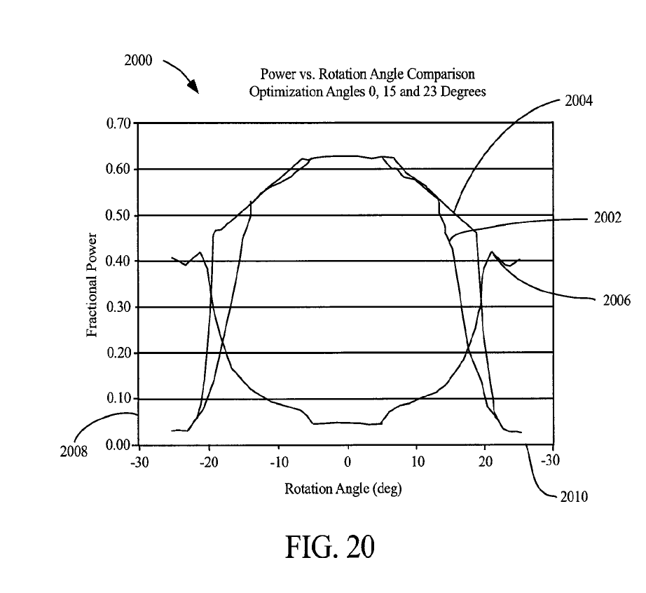

Referring next to FIG. 20, a graph 2000 illustrating power versus rotation angle for an apparatus in accordance with an embodiment of the present invention comprises functional power for the secondary minor at the zero degree line 2002, fifteen degree line 2004, and twenty three degree line 2006, functional power axis 2008, and rotation angle axis 2010.

The graph 2000 illustrates the performance of a ray tracing model as a function of the angle of incident light (rotation angle axis 2010). The functional power axis 2008 represents the amount of incident light which ultimately strikes the target. The zero degree line 2002, fifteen degree line 2004, and the twenty degree line 2006 represents the performance, or the amount of light which ultimately strikes the target, for the shape and position of the light bending apparatus determined for incident light at zero degrees, fifteen degrees, and twenty three degrees with respect to the axis of symmetry of the primary light bending apparatus by the simulation described above.

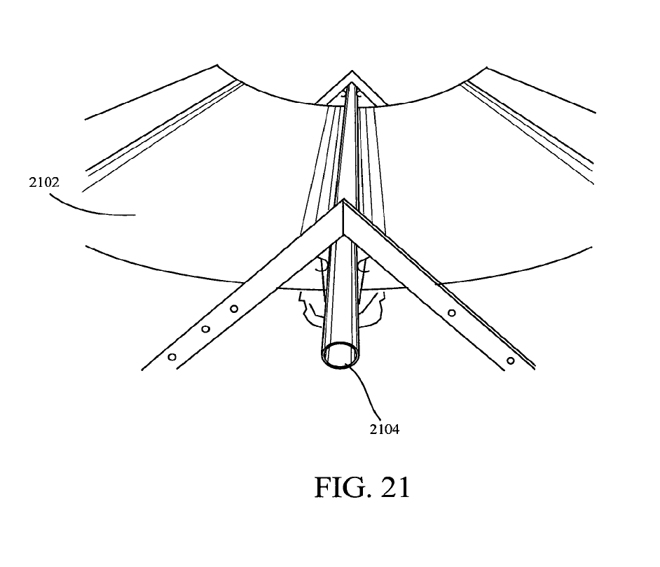

Referring next to FIG. 21, a photo depicting an apparatus in accordance with an embodiment of the present invention is illustrated comprising a light bending element 2102 and target 2104. The light bending element 2102 is a trough concentrator which concentrates light ray to a trough target 2104, such as a pipe. A working fluid may run through the pipe, as the pipe receives light energy, the working fluid heats and the light energy may then be utilized by another device.

Referring next to FIGS. 22A and 22B, three dimensional views of a container utilizing a light absorbing layer for heating a liquid in the northern or southern hemisphere in accordance with another embodiment of the present invention is illustrated comprising a container 2200, a northern boundary 2202, a southern boundary 2204, an eastern boundary 2206, a western boundary 2208, a light absorbing layer 2210, and a bottom portion 2212 of the container 2200.

The container 2200 is comprised of a northern boundary 2202, a southern boundary 2204, an eastern boundary 2206, a western boundary 2208, and a bottom portion 2212 and houses a flowable material. The northern, southern, eastern, and western boundaries 2202, 2204, 2206, and 2208 respectively correspond to the north, south, east and west portions of the container, respectively. The bottom portion 2212 is disposed below the northern, southern, eastern and western boundaries 2202, 2204, 2206, and 2208 and defines the bottom of the container 2200. The light absorbing layer 2210 may be disposed within the container along any of the northern, southern, eastern, or western boundaries 2202, 2204, 2206, and 2208 or along the bottom portion 2212 of the container 2200. In one embodiment, the light absorbing layer 2210 may be disposed along a portion of any of the northern, southern, eastern, western boundaries 2202, 2204, 2206, 2208 or the bottom portion 2212 or any combination of these boundaries. While FIGS. 22A and 22B illustrate the container 2200 as a rectangular shape, it should be appreciated that any shape may be utilized for the container and the northern, southern, eastern, and western boundaries correspond to the outer boundaries of the container in the general direction of north, south, east, and west respectively.

The light absorbing layer 2210 is utilized to absorb heat and releases the heat into the flowable material housed within the container 2200. As a result, the flowable material 2200 is passively heated by incoming light energy, such as sunlight. The light absorbing layer 2210 is disposed along the container 2200 as described above, and absorbs light energy which enters the container 2200. As the light absorbing layer 2210 is exposed to the light energy which enters the container 2200, the light absorbing layer 2210 releases the light energy as heat to the flowable material housed within the container 2200. In one embodiment, the container 2200 is a swimming pool and the flowable material is the water housed in the swimming pool. The light absorbing layer 2210 is utilized to passively heat the water in the swimming pool utilizing solar energy. When utilized with the swimming pool, the light absorbing layer 2210 is disposed along the vertical walls of the swimming pool which face the sun or on the bottom of the swimming pool to increase the amount of light energy absorbed by the light absorbing layer 2210.

In one embodiment, the light absorbing layer 2210 may be removed from the container 2200. Once the flowable material has reached a desired temperature, the light absorbing layer 2210 may be removed to prevent heating the flowable material beyond the desired temperature. In another embodiment, the light absorbing layer may be stacked upon other light absorbing layers or reoriented in order to lower the amount of light absorbed.

In the northern hemisphere, the light absorbing layer 2210 may be disposed on the northern boundary 2202 (the boundary which faces south) of the container 2200 to increase exposure to light energy. As illustrated in FIG. 22A, the heat absorbing layer 2210 is disposed upon the northern boundary 2202. When the container is a swimming pool, the light absorbing layer 2210 may be disposed along the vertical northern swimming pool walls, since these are the walls which are more exposed to sunlight in the northern hemisphere.

When the container 2200 is in the southern hemisphere, the light absorbing layer 2210 may be disposed on the southern boundary 2202 (the boundary which faces north) of the container 2200 to increase exposure to light energy. As illustrated in 22B, the light absorbing layer 2210 is disposed upon the southern boundary 2204 of the container 2200. When the container is a swimming pool, the light absorbing layer 2210 may be disposed along the vertical southern swimming pool walls, since these are the walls which are more exposed to sunlight in the southern hemisphere.

In one embodiment, the light absorbing layer 2210 may be a layer of black paint which is disposed along the boundaries of the container 2202. When the container is a swimming pool, the walls of the swimming pool may be painted black to facilitate the absorption of light energy. The painted walls of the swimming pool release the light energy as heat, therefore passively heating the water housed in the swimming pool.

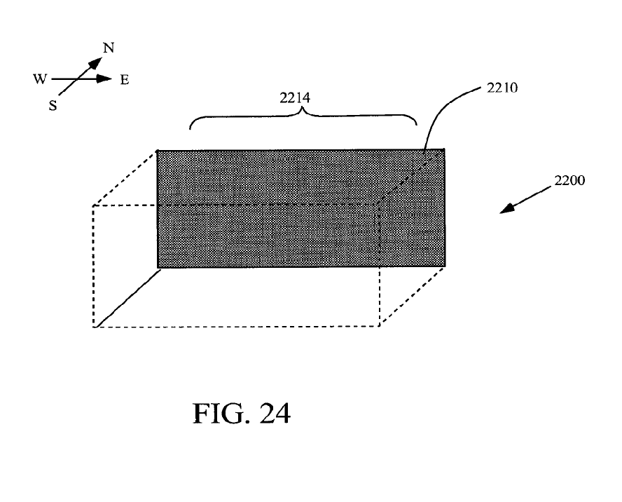

In another embodiment, the light absorbing layer 2210 may be a plurality of light absorbing elements such as black panels, tiles, or strips which are disposed within the boundaries of the container 2200 (as illustrated with respect to FIG. 24). The panels, tiles, or strips of the light absorbing layer 2210 may be removable to alter how much light energy is absorbed and therefore controlling the amount of heat released into the flowable material. When the container is a swimming pool, the tiles, panels, or strips of the light absorbing layer 2210 may be removed to control the amount of heat released into the flowing material, and therefore controlling the temperature of the pool water. In some embodiments, the light absorbing layer 2210 may be detached from the boundaries of the container 2200 and further comprises a buoyant material which allows the light absorbing layer 2210 to be utilized as insulation for the container 2200 when the container 2200 is not in use (in some embodiments, the container 2200 is a swimming pool). In other embodiments, the panels, tiles, or strips are a dark material (such as a black colored panel, tile, or strip) which facilitates the absorption of light. In another embodiment, the light absorbing elements may be stacked upon each other or the light absorbing elements may be reoriented in order to lower the amount of light absorbed.

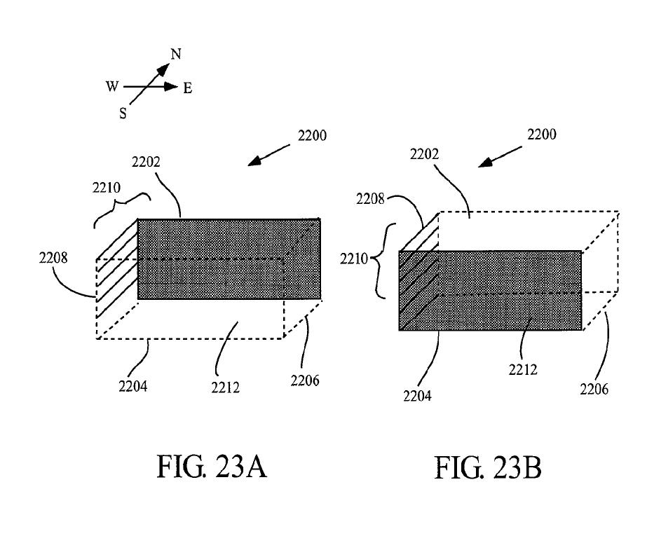

Referring next to FIGS. 23A and 23B, three dimensional views of a container utilizing a light absorbing layer for heating a liquid in the northern or southern hemisphere in accordance with another embodiment of the present invention is illustrated comprising a container 2200, a northern boundary 2202, a southern boundary 2204, an eastern boundary 2206, a western boundary 2208, a light absorbing layer 2210, and a bottom portion 2212 of the container 2200.

The various components of FIGS. 23A and 23B are similar to the various components of FIGS. 22A and 22B; however, the light absorbing layer 2210 is disposed upon multiple boundaries of the container 2200. Both FIGS. 23A and 23B illustrate the light absorbing layer 2210 is also disposed upon the western boundary 2208 (the boundary which faces east). For FIG. 23A, the container 2200 is in the northern hemisphere and the light absorbing layer 2210 is disposed upon the northern and western boundary 2202 and 2208. For FIG. 23B, the container 2200 is in the southern hemisphere and the light absorbing layer 2210 is disposed upon the southern and the western boundary 2204 and 2208. By applying the light absorbing layer 2210 to multiple boundaries, the light absorbing layer 2210 may increase exposure to the light energy.

In one embodiment, the light absorbing layer 2210 may be a layer of black paint which is disposed along the boundaries of the container 2202. When the container is a swimming pool, the walls of the swimming pool may be painted black to facilitate the absorption of light energy. The painted walls of the swimming pool release the light energy as heat, therefore passively heating the water housed in the swimming pool. It should also be appreciated that the light absorbing layer 2210 may also comprise a plurality of tiles, panels, or strips as discussed with respect to FIGS. 22A and 22B.

Referring next to FIG. 24, a three dimensional view of the container of utilizing the light absorbing layer in accordance with another embodiment of the present invention is illustrated comprising a container 2200, light absorbing layer 2210, and a plurality of light absorbing elements 2214.

As mentioned above, the light absorbing layer 2210 may be disposed upon any of the boundaries or the bottom layer of the container 2200. In addition, the light absorbing layer 2210 may comprise a plurality of light absorbing elements 2214, such as panels, tiles, or strips. The light absorbing elements 2214 may comprise a dark colored material (such as a black panel, tile, or strip) which facilitates in the absorption of light energy. The light absorbing elements 2214 may be removable to alter how much light energy is absorbed and therefore controlling the amount of heat released into the flowable material. In addition, the light absorbing elements 2214 may be moved such that the overall color of the light absorbing layer 2210 alters. When the container is a swimming pool, the various light absorbing elements 2214 may be removed to control the amount of heat released into the flowing material, and therefore controlling the temperature of the pool water. In another embodiment, the light absorbing layer may be stacked or reoriented in order to lower the amount of light absorbed.

In some embodiments, the light absorbing layer 2210 and the light absorbing elements 2214 may be detached from the boundaries of the container 2200 and further comprises a buoyant material which allows the light absorbing layer 2210 to be utilized as insulation for the container 2200 when the container 2200 is not in use (in some embodiments, the container 2200 is a swimming pool).

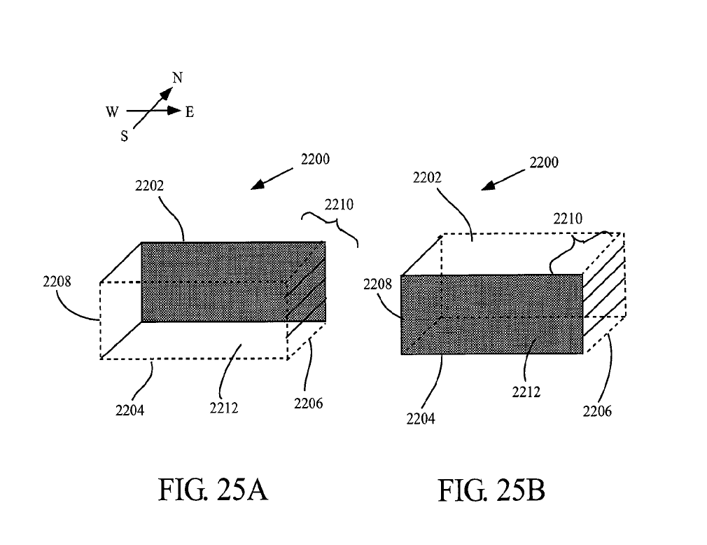

The various components of FIGS. 25A and 25B are similar to the various components of FIGS. 22A, 22B, 23A, and 23B; however, the light absorbing layer 2210 is disposed upon multiple boundaries of the container 2200. Both FIG. 25A and 25B illustrate the light absorbing layer 2210 is also disposed upon the eastern boundary 2206 (the boundary which faces west). For FIG. 25A, the container 2200 is in the northern hemisphere and the light absorbing layer 2210 is disposed upon the northern and eastern boundary 2202 and 2206. For FIG. 25B, the container 2200 is in the southern hemisphere and the light absorbing layer 2210 is disposed upon the southern and the eastern boundary 2204 and 2206. By applying the light absorbing layer 2210 to multiple boundaries, the light absorbing layer 2210 may increase exposure to the light energy.

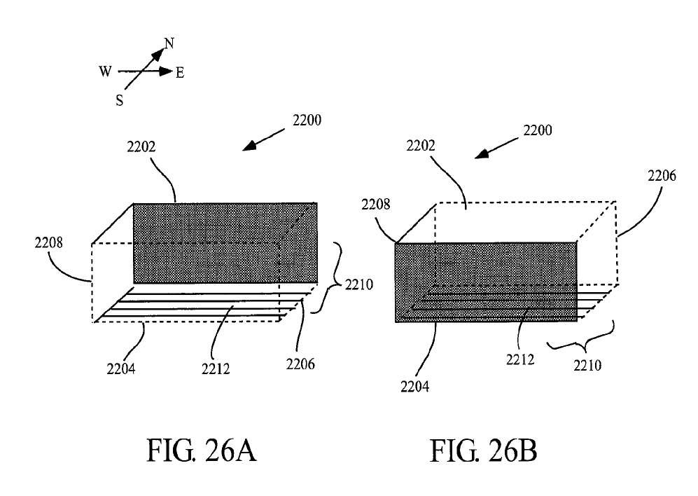

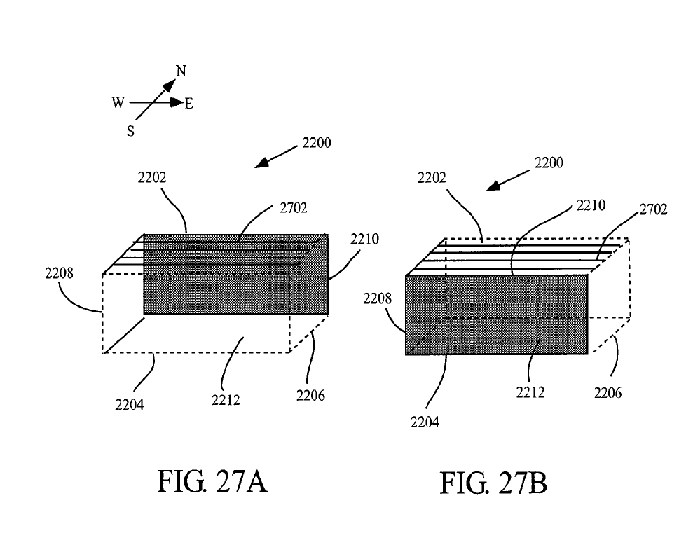

In addition, the various components of FIGS. 26A and 26B are similar to the various components of FIGS. 22A, 22B, 23A, and 23B; however, the light absorbing layer 2210 is disposed upon multiple boundaries of the container 2200. Both FIG. 26A and 26B illustrate the light absorbing layer 2210 is also disposed upon the bottom portion 2212 of the container 2200. For FIG. 26A, the container 2200 is in the northern hemisphere and the light absorbing layer 2210 is disposed upon the northern boundary 2202 and the bottom portion 2212 of the container 2200. For FIG. 26B, the container 2200 is in the southern hemisphere and the light absorbing layer 2210 is disposed upon the southern boundary 2204 and the bottom portion 2212 of the container. By applying the light absorbing layer 2210 to multiple boundaries, the light absorbing layer 2210 may increase exposure to the light energy.

It should be appreciated that the light absorbing layer may be deposited along any portion of a container. The embodiments described herein illustrate disposing the light absorbing layer along various boundaries of a container (southern, northern, eastern, and western boundaries along with the bottom portion of the container). It should be appreciated that the light absorbing layer may be disposed along any portion of these boundaries or the light absorbing layer may be disposed along any combination of a portion of these boundaries.

Referring to FIGS. 27A and 27B, a container 2200 utilizing a cover 2702 in the northern and southern hemisphere is illustrated in accordance with one embodiment of the present invention. The various components of FIGS. 27A and 27B function as described with respect to FIGS. 22A and 22B; however, a cover 2702 is further utilized to assist in the passive heating of flowable material housed within the container.

The cover 2702 is disposed at the portion of the container 2200 through which light energy (sunlight) enters the container 2200. Light energy which enters the container may pass through the cover 2702 before reaching the light absorbing layer 2210. In some embodiments, the cover 2702 comprises a transparent, translucent, or opaque material which allows the passage of light energy through the cover 2702. It should also be appreciated that the cover 2702 may be disposed along a part of the portion of the container 2200 through which light energy (sunlight) enters the container 2200. As the light absorbing layer 2210 is exposed to the light energy which enters the container 2200 and through the cover 2702, the light absorbing layer 2210 releases the light energy as heat to the flowable material housed within the container 2200. The cover 2702 then acts as an insulator for the heat and the flowable material. In addition, the cover 2702 may be utilized to reduce evaporation of the flowable material, greatly minimizing the cost for heating the flowable material.

In one embodiment, the container 2200 is a swimming pool and the flowable material is the water housed in the swimming pool. The light absorbing layer 2210 is utilized to passively heat the water in the swimming pool utilizing solar energy. When utilized with the swimming pool, the light absorbing layer 2210 is disposed along the vertical walls of the swimming pool which face the sun or on the bottom of the swimming pool to increase the amount of light energy absorbed by the light absorbing layer 2210. In addition, the cover 2702 may be utilized to further facilitate in heating the pool by minimizing evaporation of the pool water and allowing insulation of the heat. FIGS. 27A and 27B illustrate the use of a cover 2702 along with a light absorbing layer 2210 in a container in the northern or southern hemisphere, respectively.

While the invention herein disclosed has been described by means of specific embodiments, examples and applications thereof, numerous modifications and variations could be made thereto by those skilled in the art without departing from the scope of the invention set forth in the claims.

What is claimed is:

1. An apparatus for directing wave energy comprising:
a target, wherein the target is configured for collecting the wave energy from a wave source; and
a wave bending element disposed in a wave path of at least one ray of the wave energy between the wave source and the target, wherein the wave bending element is configured for collection of the wave energy as an angle of incidence of at least one ray of the wave energy changes over time relative to the wave bending element, the wave bending element is configured to direct the wave energy to the target, wherein the wave bending element and the target move relative to each other, movement of the wave bending element and the target relative to each other being a function of at least the angle of incidence of at least one ray of the wave energy.

2. The apparatus of claim 1, further comprising:
an additional wave bending element disposed in the wave path of at least one ray of the wave energy between the wave source and the target, wherein the additional wave bending element is configured to direct the wave energy to the target.

3. The apparatus of claim 2, further comprising:
a further wave bending element disposed in the wave path of at least one ray of the wave energy between the wave source and the target, wherein the wave bending element is configured to direct the wave energy to the target.

4. The apparatus of claim 3, wherein the further wave bending element and the wave bending element move relative to each other, movement of the further wave bending element and the wave bending element relative to each other being a function of at least the angle of incidence of at least one ray of the wave energy.

5. The apparatus of claim 3, wherein the further wave bending element and the target move relative to each other, movement of the further wave bending element and the target relative to each other being a function of at least the angle of incidence of at least one ray of the wave energy.

6. The apparatus of claim 3, wherein the wave bending element directs the wave energy to the additional wave bending element, the addition wave bending element directs the wave energy to the further wave bending element, the further wave bending element directs the wave energy to the target.

7. The apparatus of claim 3, wherein the additional wave bending element directs the wave energy to the wave bending element, the wave bending element directs the wave energy to the further wave bending element, the further wave bending element directs the wave energy to the target.

8. The apparatus of claim 3, wherein the further wave bending element further comprises a tertiary mirror.

9. The apparatus of claim 2, wherein the additional wave bending element and the wave bending element move relative to each other, movement of the additional wave bending element and the wave bending element relative to each other being a function of at least the angle of incidence of at least one ray of the wave energy.

10. The apparatus of claim 2, wherein the additional wave bending element and the target move relative to each other, movement of the additional wave bending element and the target relative to each other being a function of at least the angle of incidence of at least one ray of the wave energy.

11. The apparatus of claim 2, wherein the additional wave bending element directs wave energy to the wave bending element, the wave bending element directs the wave energy to the target.

12. The apparatus of claim 2, wherein the wave bending element directs the wave energy to the additional wave bending element, the additional wave bending element directs the wave energy to the target.

13. The apparatus of claim 2, wherein a shape of the additional wave bending element is determined at least by a coma of the wave bending element.

14. The apparatus of claim 2, wherein a shape of the wave bending element is determined at least by a coma of the additional wave bending element.

15. The apparatus of claim 2, wherein the additional wave bending element further comprises a tertiary mirror.

16. The apparatus of claim 2, wherein a shape of the wave bending element and a shape of the additional wave bending element for directing the wave energy is determined at least through an environmental simulation, wherein the environmental simulation computes an amount of wave energy collection from the wave path of at least one ray of the wave energy, the wave path of the at least one ray of the wave energy is a function of the at least the angle of incidence of the at least one ray of the wave energy, the shape of the wave bending element, and the shape of the additional wave bending element.

17. The apparatus of claim 1, wherein the target further comprises at least one point target.

18. The apparatus of claim 1, wherein the target further comprises at least one trough target.

19. The apparatus of claim 1, wherein the target further comprises at least one photovoltaic cell.

20. The apparatus of claim 1, wherein the target further comprises at least one wave energy absorbing pipe enveloping a flowable material.

21. The apparatus of claim 1, wherein the target is disposed between the wave source and the wave bending element.

22. The apparatus of claim 1, wherein the wave bending element is disposed between the wave source and the target.

23. The apparatus of claim 1, further comprising:
a follower coupled to the wave bending element, wherein the follower is configured to maintain a constant distance between the wave bending element and the target

24. The apparatus of claim 1, wherein the wave bending element further comprises a reflective device.

25. The apparatus of claim 24, wherein the reflective device is a mirror.

26. The apparatus of claim 1, wherein the wave bending element further comprises a lens.

27. The apparatus of claim 1, wherein the wave bending element is shaped for two-dimensional focusing of the wave energy to the target.

28. The apparatus of claim 1, wherein the wave bending element is shaped for one-dimensional focusing of the wave energy to the target.

29. The apparatus of claim 1, wherein the wave bending element is comprised of a flexible reflective material.

30. The apparatus of claim 1, wherein a shape of the wave bending element for directing the wave energy is determined at least through an environmental simulation, wherein the environmental simulation computes an amount of wave energy collection from the wave path of at least one ray of the wave energy, the wave path of the at least one ray of the wave energy is a function of the at least the angle of incidence of the at least one ray of the wave energy and the shape of the wave bending element.

31. The apparatus of claim 1, wherein the wave energy, the wave source, and the wave bending element further comprises light energy, a light source, and a light bending element, wherein a light bending elements is configured to be disposed in a light path of at least one ray of the light energy between the light source and the target, wherein the light bending element is configured for collection of the light energy as an angle of incidence of at least one ray of the light energy changes over time relative to the light bending element, the light bending element is configured to direct the light energy to the target, wherein the light bending element and the target move relative to each other, movement of the light bending element and the target relative to each other being a function of at least the angle of incidence of at least one ray of the light energy.

32. The apparatus of claim 1, wherein the wave energy is at least one of a sound wave, a compression wave, a water wave, and a radar wave.

33. A method for directing wave energy comprising:
receiving at least one ray of the wave energy at a wave bending element at an angle of incidence upon the wave bending element, wherein the wave bending element is disposed in a wave path of at least one ray of the wave energy between a wave source and a target;
directing at least one ray of the wave energy from the wave bending element to the target;
moving the wave bending element and the target relative to each other, wherein movement of the wave bending element and the target relative to each other being a function of at least an angle of incidence of at least one ray of the wave energy; and
collecting the at least one ray of the wave energy at the target.

34. The method of claim 33, prior to collecting the at least one ray of the wave energy at the target, further comprises:
receiving the at least one ray of the wave energy at an additional wave bending element, wherein the additional wave bending element is disposed in the wave path of at least one ray of the wave energy between the wave source and the target; and
directing the at least one ray of the wave energy from the additional wave bending element to the target.

35. The method of claim 34, prior to collecting the at least one ray of the wave energy at the target, further comprises:
receiving the at least one ray of the wave energy at a further wave bending element, wherein the further wave bending element is disposed in the wave path of at least one ray of the wave energy between the wave source and the target; and
directing the at least one ray of the wave energy from the further wave bending element to the target.

36. The method of claim 35, prior to directing the at least one ray of the wave energy from the further wave bending element to the target, further comprises:
moving the further wave bending element and the wave bending element relative to each other, movement of the further wave bending element and the wave bending element relative to each other being a function of at least the angle of incidence of at least one ray of the wave energy.

37. The method of claim 35, prior to directing the at least one ray of the wave energy from the further wave bending element to the target, further comprises:
moving the further wave bending element and the target relative to each other, movement of the further wave bending element and the target relative to each other being a function of at least the angle of incidence of at least one ray of the wave energy.

38. The method of claim 35, wherein directing the at least one ray of the wave energy from the wave bending element to the target further comprises:
directing the at least one ray of the wave energy from the wave bending element to the additional wave bending element;
receiving the at least one ray of the wave energy at the additional wave bending element;
directing the at least one ray of the wave energy from the additional wave bending element to the further wave bending element;
receiving the at least one ray of the wave energy at the further wave bending element; and
directing the at least one ray of the wave energy from the further wave bending element to the target.

39. The method of claim 35, wherein directing the at least one ray of the wave energy from the additional wave bending element to the target further comprises:
directing the at least one ray of the wave energy from the additional wave bending element to the wave bending element;
receiving at least one ray of the wave energy at the wave bending element;
directing the at least one ray of the wave energy from the wave bending element to the further wave bending element;
receiving the at least one ray of the wave energy at the further wave bending element; and
directing the at least one ray of the wave energy from the further wave bending element to the target.

40. The method of claim 35, wherein further wave bending element comprises a tertiary mirror.

41. The method of claim 34, prior to directing the at least one ray of the wave energy from the additional wave bending element to the target, further comprises:
moving the additional wave bending element and the wave bending element relative to each other, movement of the additional wave bending element and the wave bending element relative to each other being a function of at least the angle of incidence of at least one ray of the wave energy.

42. The method of claim 34, prior to directing the at least one ray of the wave energy from the additional wave bending element to the target, further comprises:
moving the additional wave bending element and the target relative to each other, movement of the additional wave bending element and the target relative to each other being a function of at least the angle of incidence of at least on ray of the wave energy.

43. The method of claim 34, wherein directing the at least one ray of the wave energy from the additional wave bending element to the target further comprises:
directing the at least one ray of the wave energy from the additional wave bending element to the wave bending element;
receiving at least one ray of the wave energy at the wave bending element; and
directing at least one ray of the wave energy from the wave bending element to the target.

44. The method of claim 34, wherein directing at least one ray of the wave energy from the wave bending element to the target further comprises:
directing the at least one ray of the wave energy from the wave bending element to the additional wave bending element;
receiving at least one ray of the wave energy at the additional wave bending element; and
directing at least one ray of the wave energy from the additional wave bending element to the target.

45. The method of claim 34, further comprising:
shaping the additional wave bending element, wherein shaping of the additional wave bending element is determined at least by a coma of the wave bending element.

46. The method of claim 34, further comprising:
shaping the wave bending element, wherein shaping of the wave bending element is determined at least by a coma of the additional wave bending element.

47. The method of claim 34, wherein the additional wave bending element further comprises a tertiary mirror.

48. The method of claim 34, further comprising:
shaping the wave bending element and the additional wave bending element for directing the at least one ray of the wave energy, wherein a shape of the wave bending element and a shape of the additional wave bending element is determined at least through an environmental simulation, wherein the environmental simulation computes an amount of wave energy collection from the wave path of the at least one ray of the wave energy, the wave path of the at least one ray of the wave energy is a function of the at least the angle of incidence of the at least one ray of the wave energy, the shape of the wave bending element, and the shape of the additional wave bending element.

49. The method of claim 33, wherein the target further comprises at least one point target.

50. The method of claim 33, wherein the target further comprises at least one through target.

51. The method of claim 33, wherein the target further comprises at least one photovoltaic cell.

52. The method of claim 33, wherein the target further comprises at least one wave energy absorbing pipe enveloping a flowable material.

53. The method of claim 33, wherein the target is disposed between the wave source and the wave bending element.

54. The method of claim 33, wherein the wave bending element is disposed between the wave source and the target.

55. The method of claim 33, further comprising:
maintaining a constant distance between the wave bending element and the target as the wave bending element and the target move relative to each other, wherein a follower coupled to the wave bending element is configured to provide the maintaining.

56. The method of claim 33, wherein the wave bending element further comprises a reflective device.

57. The method of claim 56, wherein the reflective device is a mirror.

58. The method of claim 33, wherein wave bending element further comprises a lens.

59. The method of claim 33, further comprising:
shaping the wave bending element for two-dimensional focusing of the wave energy to the target.

60. The method of claim 33, further comprising:
shaping the wave bending element for one-dimensional focusing of the wave energy to the target.

61. The method of claim 33, wherein the wave bending element is comprised of a flexible reflective material.

62. The method of claim 33, further comprising:
determining a shape of the wave bending element for directing wave energy through at least an environmental simulation, wherein the environmental simulation computes an amount of wave energy collection from the wave path of the at least one ray of the wave energy, the wave path of the at least one ray of the wave energy is a function of the at least the angle of incidence of the at least one ray of the wave energy and the shape of the wave bending element.

63. The method of claim 33, wherein the wave energy, the wave source, and the wave bending element further comprises light energy, a light source, and a light bending element.

64. The method of claim 33, wherein the wave energy is at least one of a sound wave, a compression wave, a water wave, and a radar wave.

65. A method for heating a flowable material, comprising:
applying a light absorbing layer to at least a portion of a container, wherein the container houses the flowable material;
absorbing light energy at the light absorbing layer; and
releasing the light energy as heat form the light absorbing layer to the flowable material in the container.

66. The method of claim 65, further comprising:
removing the light absorbing layer from the container.

67. The method of claim 65, wherein the applying the light absorbing layer to at least the portion of the container further comprises applying the light absorbing layer to at least the portion of the container, wherein the container comprises a swimming pool and the flowable material comprises water.

68. The method of claim 65, wherein applying the light absorbing layer to at least the portion of the container further comprises applying the light absorbing layer to at least a portion of a sun facing boundary of a swimming pool.

69. The method of claim 68, wherein the at least one sun facing boundary comprises at least a portion of a south facing boundary of the swimming pool.

70. The method of claim 68, wherein the at least one sun facing boundary comprises at least a portion of a north facing boundary of the swing pool.

71. The method of claim 65, wherein applying the light absorbing layer to at least the portion of the container further comprises applying the light absorbing layer to at least a portion of an east facing boundary of a swimming pool.

72. The method of claim 65, wherein applying the light absorbing layer to at least the portion of the container further comprises applying the light absorbing layer to at least a portion of a west facing boundary of a swimming pool.

73. The method of claim 65, wherein the light absorbing layer comprises black paint.

74. The method of claim 65, wherein the light absorbing layer comprises a plurality of light absorbing elements.

75. The method of claim 74, further comprising:
removing at least one of the plurality of light absorbing elements from the container.

76. The method of claim 74, further comprising:
reorienting at least one of the plurality of light absorbing elements within the container.

77. The method of claim 74, further comprising:
stacking at least one of the plurality of the light absorbing element upon another one of the plurality of the light absorbing elements.

78. The method of claim 65, further comprising:
applying a cover to at least the portion of a opening of the container, wherein the cover further insulates the released light energy from the light absorbing layer within the container.
